(19) United States
(12) Patent Application Publication
(10) Pub. No.: US 2016/0298030 A1
(43) Pub. Date: Oct. 13, 2016

(54) METALLIC AND SEMICONDUCTOR NANOTUBES, NANOCOMPOSITE OF SAME, PURIFICATION OF SAME, AND USE OF SAME

(71) Applicants: Fotios Papadimitrakopoulos, West Hartford, CT (US); Darlington Abanulo, Storrs, CT (US)

(72) Inventors: Fotios Papadimitrakopoulos, West Hartford, CT (US); Darlington Abanulo, Storrs, CT (US)

(21) Appl. No.: 14/574,994

(22) Filed: Dec. 18, 2014

Related U.S. Application Data
(60) Provisional application No. 61/919,405, filed on Dec. 20, 2013.

(51) Int. Cl. C09K 11/65; H01L 29/786; H02N 11/00; H01L 29/06; H01L 23/528; H01L 23/532; C01B 31/02; H01L 29/49

(52) U.S. Cl. CPC C09K 11/65; C01B 31/0266; C01B 31/026; C01B 31/0273; H01L 29/786; H01L 29/4908; H01L 29/4966; H01L 29/0665; H01L 23/528; H01L 23/53276; H01L 23/5328; H02N 11/006; C01B 2202/02; C01B 2202/22; B82Y 40/00

(57) ABSTRACT

A braided nanocomposite comprises a plurality of superhelix nanocomposites reversibly combined in a braided helical configuration, each of the superhelix nanocomposites comprises: an (n,m)-single wall carbon nanotube ((n,m)-SWNT); a plurality of flavin moieties disposed in a helix which is self-assembled around the (n,m)-SWNT; and a writhe formed by coiling of the (n,m)-SWNT, wherein the plurality of superhelix nanocomposites reversibly combines to form the braided nanocomposite. A method for removing a surface defect from nanocomposites comprises: disposing a nanocomposite in a first medium, the nanocomposite comprising: an (n,m)-SWNT; and a plurality of flavin moieties disposed on the (n,m)-SWNT, a portion of the plurality of flavin moieties being arranged in a helix on the (n,m)-SWNT; contacting the nanocomposite with a second medium; and annealing the surface defect among the plurality of flavin moieties disposed on the (n,m)-SWNT to remove the surface defect from the nanocomposite to form an annealed nanocomposite.

### CROSS REFERENCE TO RELATED APPLICATION

This US Non-Provisional application claims the benefit of U.S. Provisional Application Ser. No. 61/919,405, filed 20 Dec. 2013, the entire contents of which are hereby incorporated by reference.

### STATEMENT REGARDING FEDERALLY SPONSORED RESEARCH

This invention was made with government support under Grant No. FA9550-09-1-0201 awarded by the Air Force Office of Scientific Research and Grant No. CBET-0828771/0828824 awarded by the National Science Foundation. The government has certain rights in the invention.

### BACKGROUND

Single wall carbon nanotubes (SWNTs) have remarkable optical, electrical, and mechanical properties, including high strength, modulus, and flexibility while having a low weight and superb temperature and chemical stability.

Single wall carbon nanotubes generally have a single carbon wall with outer diameters of greater than or equal to about 0.7 nanometers (nm). Single wall carbon nanotubes generally have various lengths and can have aspect ratios that are from about 5 to about 10,000. In general, single wall carbon nanotubes exist in the form of rope-like-aggregates. These aggregates are commonly termed “ropes” and are formed as a result of Van der Waal's forces between the individual carbon nanotubes. The individual nanotubes in the ropes may slide against one another and rearrange themselves within the rope in order to minimize the free energy of the rope. Ropes can include from two to thousands of nanotubes. Single wall carbon nanotubes exist in the form of metallic nanotubes and semiconducting nanotubes. Metallic (met) nanotubes display electrical characteristics similar to metals, while semiconducting (sem-) nanotubes exhibit a well-defined band gap and are electrically semiconducting.

The configuration of the carbon lattice in single wall carbon nanotubes can be thought of as being derived from rolling up a graphene sheet such that bonds are formed between certain carbon atoms at the peripheral edge of the graphene sheet. In general, the manner in which the graphene sheet is rolled up produces nanotubes of various helical structures. Several SWNT structures as well as lattice vectors (a₁ and a₂) are shown in FIG. 1. With reference to FIG. 1, lattice unit vectors a₁ and a₂ respectively are multiplied by Hamada indices n and m (integer numbers) and added to produce the resultant Hamada vector Cₕ (i.e., Cₕ=n·a₁+m·a₂). The atoms of the lattice at the tail and head of the Hamada vector Cₕ correspond to atoms in the graphene sheet that are bonded together in the final nanotube structure, and atoms nearest the Hamada vector in the graphene sheet correspond to the repeat pattern of the lattice atoms along the length of the nanotube. For example, zigzag nanotubes have (n,0) lattice vector values, while armchair nanotubes have (n,n) lattice vector values. Zigzag and armchair nanotubes constitute the two possible achiral confirmations. All other (n,m) lattice vector values yield chiral nanotubes such as the (8,1) chiral nanotube shown in FIG. 1. Right or left helical patterns of different (n,m) chirality carbon nanotubes are referred to as “handedness” and correspond to either (n,m) or (m,n) structures.

Carbon nanotubes can be used in a wide variety of applications such as rendering plastics electrically conductive, in semiconductors, opto-electronic and electro-optical device applications, and the like. In applications involving the well-defined optical and electronic properties of one or few (n,m)-SWNT, it is generally desirable to separate carbon nanotubes from the ropes that hold them together. Bundling of carbon nanotubes presents a challenge to their separation as well as realizing the potential of the nanotubes in high-end applications.

Separation of single wall carbon nanotubes based on their electrical conductivity characteristics has been conducted by amine-based selective solubilization, deoxyribonucleic acid (DNA) based anionic chromatography, dielectrophoresis, electrophoresis, selective reactivity against reactive reagents, density gradient centrifugation, and by other methods. Separation of single wall carbon nanotubes based on their lengths has been mainly accomplished by size-exclusion chromatographic techniques, capillary electrophoresis, and field-flow fractionation. Separation of single wall carbon nanotubes by diameter has been demonstrated by density gradient centrifugation as well as by DNA-based anionic chromatography. Separation of single wall carbon nanotubes based on their handedness or chirality was recently demonstrated by the interaction of a chiral bi-porphyrin moiety with single wall carbon nanotubes.

Although some of these separation techniques have been moderately successful, bundling still impedes nanotube separation and confines most uses to processing that involves dilute dispersions of carbon nanotubes. Although DNA-based separation affords multi-level separation of nanotubes according to type (electrical conductivity characteristics), length, diameter and chirality, such separation is afforded only for specific DNA sequences (i.e., d(GT)n oligomers), which clearly is a major hurdle in terms of commercialization and scale-up due to the prohibitive cost of DNA. Moreover, desorbing DNA oligomers from the single wall carbon nanotubes to obtain pristine nanotubes is difficult, adding another layer of complexity to DNA-processed single wall carbon nanotubes.

The art is always receptive to materials or methods that produce purer carbon nanotubes and composites thereof as well as cheaper and more efficient processes for carbon nanotube separation and usage.

### SUMMARY

Disclosed herein is a method for enriching an initial concentration of (8,6)-SWNTs, (7,7)-SWNTs, or a combination thereof, from a plurality of (n,m)-SWNTs, the method comprising: dispersing the plurality of (n,m)-SWNTs in a first medium comprising flavin moieties under conditions effective for the flavin moieties to self-assemble in a wrapped pattern around the (n,m)-SWNTs, to form a nanocomposite; contacting the nanocomposite with a second medium that is immiscible with the first medium under conditions effective to enrich, in the first medium, the concentration of an (8,6)-SWNT nanocomposite, (7,7)-SWNT nanocomposite, or a combination thereof relative to the initial concentration in the plurality of (n,m)-SWNTs; and separating the first medium from the second medium.

Also disclosed herein is a method for removing a surface defect in a nanocomposite, the method comprising: disposing a nanocomposite in a first medium, the nanocomposite comprising: an (n,m)-single wall carbon nanotube ((n,m)-SWNT); and a plurality of flavin moieties disposed on the (n,m)-SWNT, a portion of the plurality of flavin moieties being arranged in a helix on the (n,m)-SWNT; contacting the nanocomposite with a second medium; and annealing the surface defect among the plurality of flavin moieties disposed on the (n,m)-SWNT to remove the surface defect from the nanocomposite to form an annealed nanocomposite.

Further disclosed is a method for producing a superhelix nanocomposite, the method comprising: forming a nanocomposite comprising: an (n,m)-single wall carbon nanotube ((n,m)-SWNT); and a helix comprising flavin moieties wrapped around the (n,m)-SWNT; and coiling the nanocomposite to form the superhelix nanocomposite which comprises a writhe.

Additionally, disclosed herein is a method for inducing photoluminescent emission in a superhelix nanocomposite, the method comprising: irradiating a medium comprising a plurality of superhelix nanocomposites with primary radiation comprising an excitation wavelength; irradiating the medium with secondary radiation comprising the excitation wavelength and a quenching wavelength; and collecting photoluminescent emission from the medium, wherein the superhelix nanocomposite comprises: an (n,m)-single wall carbon nanotube ((n,m)-SWNT); a helix comprising a plurality of flavin moieties wrapped around the (n,m)-SWNT; and a writhe formed in response to coiling of the (n,m)-SWNT.

Disclosed herein too is a braided nanocomposite comprising: a plurality of superhelix nanocomposites reversibly combined in a braided helical configuration, each of the superhelix nanocomposites comprising: an (n,m)-single wall carbon nanotube ((n,m)-SWNT); a plurality of flavin moieties disposed in a helix which is self-assembled around the (n,m)-SWNT; and a writhe formed by coiling of the (n,m)-SWNT, wherein the plurality of superhelix nanocomposites reversibly combines to form the braided nanocomposite in response to a concentration of the superhelix nanocomposites being greater than a critical concentration for forming the braided nanocomposite; the (n,m)-SWNT comprises an (n,m)-sem-SWNT, (n,m)-met-SWNT, or a combination thereof; and the helix has a continuous length from 200 nm to 700 nm, based on a longitudinal distance along the (n,m)-SWNT.

Disclosed herein too is a nanosensor system comprising: a power unit to generate power; a sensor configured to generate an electrical signal in response to sensing an event and electrically connected to the power unit; a signal converter to receive and convert the electrical signal into an electrical pulse and to output the electrical pulse, the signal converter being electrically connected to the power unit and sensor; and an optical modulator comprising: a light source to output a quenching wavelength which is modulated between an on-state and an off-state at a frequency of the electrical pulse from the signal converter, the light source being electrically connected to the power unit and signal converter; an optical cavity comprising: a cavity to contain a composition comprising the braided nanocomposite; and a plurality of walls disposed about the cavity to transmit radiation.

Disclosed herein too is a nanotransistor comprising: a source electrode; a drain electrode opposingly disposed to the source electrode; and a gate electrode interposed between the source electrode and drain electrode, the gate electrode comprising the braided nanocomposite.

Disclosed herein too is a nanoactuator comprising: a medium; and the braided nanocomposite disposed in the medium, wherein the nanoactuator is configured to be actuated between a non-actuated state and an actuated state in response to a change in a condition, in the non-actuated state the plurality of superhelix nanocomposites are spaced apart by a separation such that the braided helical configuration is absent in the braided nanocomposite; and in the actuated state the separation is removed in response to the change in condition such that the plurality of superhelix nanocomposites reversibly combines to form the braided helical configuration.

Disclosed herein too is a structural nanoprobe comprising: a medium; and the braided nanocomposite disposed in the medium, wherein the plurality of superhelix nanocomposites in the braided nanocomposite comprises: a first superhelix nanocomposite in which the (n,m)-SWNT is an (n,m)-sem-SWNT; and a second superhelix nanocomposite in which the (n,m)-SWNT is an (n,m)-met-SWNT, and the braided nanocomposite has a Fano effect such that: the (n,m)-sem-SWNT emits photoluminescent emission in response to irradiation with primary radiation comprising an excitation wavelength, the photoluminescent emission from the (n,m)-sem-SWNT is quenched by the (n,m)-met-SWNT in response to irradiation with secondary radiation comprising the excitation wavelength and a quenching wavelength when the first and second superhelix nanocomposites have the braided helical configuration, and the photoluminescent emission from the (n,m)-sem-SWNT is emitted in response to irradiation with the secondary radiation when the first and second superhelix nanocomposites are spaced apart by a separation such that the braided helical configuration is absent in the braided nanocomposite.

The above described and other features are exemplified by the following figures and detailed description.

### BRIEF DESCRIPTION OF THE DRAWINGS

Referring now to the figures, which are embodiments, and wherein like elements are numbered alike:

FIG. 1 shows different chirality (n,m) nanotubes and unit vectors in a graphene sheet;

FIG. 2 shows chemical structures of riboflavin, flavin mononucleotide (FMN), flavin adenine dinucleotide (FAD), and 10-dodecyl-7, 8-dimethyl-10H-benzo[g]pteridine-2,4-dione (FC12);

FIG. 3 shows a hydrogen bonding configuration for flavin moieties and a flavin helix arrangement;

FIG. 4 shows a distance dependence of photoluminescent emission quenching in a braided nanocomposite;

FIG. 5 shows antigen binding by superhelix nanocomposites and formation of braided nanocomposites;

FIG. 6 shows extension of braided nanocomposites that are attached to an antigen;

FIG. 7 shows an exemplary nanosensor system;

FIG. 8 shows a micrograph of an arrangement of sem- and met-SWNTs in a transistor;

FIG. 9 shows a solution phase nanotransistor that includes a braided nanocomposite;

FIG. 10 shows a solid state nanotransistor that includes a braided nanocomposite;

FIG. 11 shows an actuated and non-actuated state of a nanoactuator that includes a braided nanocomposite;

FIG. 12 shows a structural nanoprobe that includes a braided nanocomposite;

FIG. 13 shows dispersion and enrichment of an FMN/SWNT nanocomposite;

FIG. 14 shows absorption spectra and photoluminescent emission maps before and after cyclohexanone extraction for FMN/SWNT nanocomposites;

FIG. 15 shows a photoluminescent emission maps before and after extraction with cyclohexanone for FMN/SWNT nanocomposites and also for sodium cholate exchanged FMN/SWNTs;

FIG. 16 shows absorption spectra for sodium cholate exchanged FMN/SWNTs before and after treatment with cyclohexanone;

FIG. 17 shows a Raman correlation chart and the Raman spectra observed for the radial breathing mode of (7,7)-SWNTs;

FIG. 18 shows a Weisman plot for various (n,m)-SWNTs along with the FMN nanocomposite enriched (8,6)-sem-SWNT and (7,7)-met-SWNT that have comparable diameters and chiral angles;

FIG. 19 shows syn- and anti-confirmation for FMN and a FMN helix disposed around and M-(8,6)-SWNT;

FIG. 20 shows a graph of circular dichroism and optical absorbance versus wavelength for FMN/SWNT nanocomposites;

FIG. 21 shows a comparison of optical behavior of FMN/SWNTs after extraction with ethyl acetate and cyclohexanone;

FIG. 22 shows a helical defect of FMN-wrapped SWNTs before and after annealing to remove the defect;

FIG. 23 shows an effect on melting temperature of an FMN helix of FMN/SWNTs as a function of extraction conditions;

FIG. 24 shows a 1D X-ray diffraction spectrum of enriched FMN/SWNTs;

FIG. 25 shows a 2D X-ray diffraction pattern of enriched FMN/SWNTs;

FIG. 26 shows improvement of quasi-epitaxy of flavin by gradually twisting an underlying SWNT along with an atomic force micrograph of a superhelically twisted (writhed) FMN/SWNT nanocomposite;

FIG. 27 shows atomic force microscopy (AFM) micrographs of superhelix nanocomposite and their relative periodicities;

FIG. 28 shows surfactant exchange titration data for braided nanocomposites of FMN/SWNTs titrated with sodium dodecylbenzenesulfonate and AFM micrographs before and after surfactant exchange;

FIG. 29 shows AFM micrographs for FMN/SWNTs and SDBS/SWNTs and their respective height histograms;

FIG. 30 shows a PLE map for an FMN/SWNT braided nanocomposites;

FIG. 31 shows dilation of a braided nanocomposite;

FIG. 32 shows a graph of PLE intensity versus wavelength for various concentrations of FMN/SWNT nanocomposites;

FIG. 33 shows optical characteristics of FMN/SWNT braided nanocomposites that include only superhelix nanocomposites of (8,6)-SWNTs; and

FIG. 34 shows a graph of the photoluminescent intensity versus pH for nanocomposites of FMN/SWNTs.

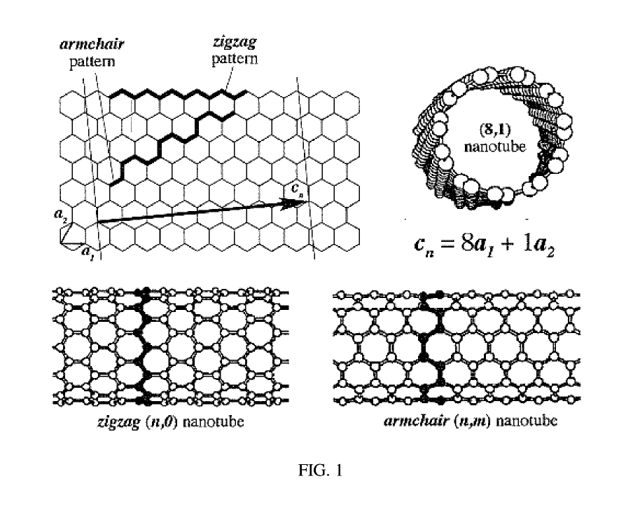

### DETAILED DESCRIPTION

It has been found that a simple and rapid liquid-liquid extraction provides flavin-coated nanotubes having an enrichment in a select number of nanotube species with a preferred seamless flavin geometrical configuration on the nanotube. Additionally, treatment of the flavin-coated nanotubes with certain media removes defects in the flavin coating. Combinations of such flavin-coated nanotube species are beneficially useful in optical probes having differential emission such that composites of the flavin-coated nanotube species can be implemented in diverse applications such as an immunosensor or an electrical or mechanical device or method.

In an embodiment, a nanocomposite comprises an (n,m)-single wall carbon nanotube ((n,m)-SWNT) and a plurality of flavin moieties that are disposed on the (n,m)-SWNT in a self-assembling pattern that is orderly wrapped around the (n,m)-SWNT. Here, the (n,m)-SWNT can be a semiconducting or metallic SWNT, respectively referred to as an (n,m)-sem-SWNT or (n,m)-met-SWNT. According to an embodiment, the (n,m)-SWNT includes, for example, an (8,6)-SWNT, (7,7)-SWNT, or a combination thereof. In addition, the self-assembling pattern can be a helix of flavin moieties surroundingly disposed on the (n,m)-SWNT.

Flavin moieties, such as, for example, flavin mononucleotide, flavin adenine dinucleotide (FAD), and other flavin derivatives (described in detail below) exhibit strong π-π interaction with the side-walls of the single wall carbon nanotubes. This strong π-π interaction with the carbon nanotube can be used to produce effective dispersion and solubilization of the carbon nanotubes that are devoid of carbonaceous impurities. The tight helical wrapping of the self-assembled helix also affords the epitaxial selection of particular, select (n,m) chirality nanotubes or (n,n) achiral nanotubes along with the exclusion of physisorbed or chemisorbed impurities on the nanotube side walls. The seamless flavin helix around nanotubes provides a uniform, protecting sheath that excludes oxygen, a well-known electron acceptor, which leads to hole doping and luminescence quenching through non-radiative Auger processes. This opens an array of new frontiers in single wall carbon nanotube (SWNT) photophysics and device applications, where semiconductor purity is combined with hierarchical organization for the manipulation of nano structured systems.

Unlike DNA, whose oligomeric or polymeric sugar-phosphate main chain provides the backbone for helical wrapping of the carbon nanotubes, in the case of molecules that comprise flavin moieties, such wrapping is afforded via (i) charge-transfer (between the flavin moieties and the carbon nanotubes) along the nanotube side walls and (ii) hydrogen-bonding (between adjacent flavin moieties) to propagate the helix. This renders the formation of a self-assembled structure, which can be readily dissolved away under certain conditions, unlike DNA. Depending on the strength of the interaction between the flavin moieties and underlying SWNT carbon lattice, different (n,m)-SWNTs have higher association strengths with the flavin moieties, which allows for the selective separation of (n,m)-SWNT species among a distribution of such species.

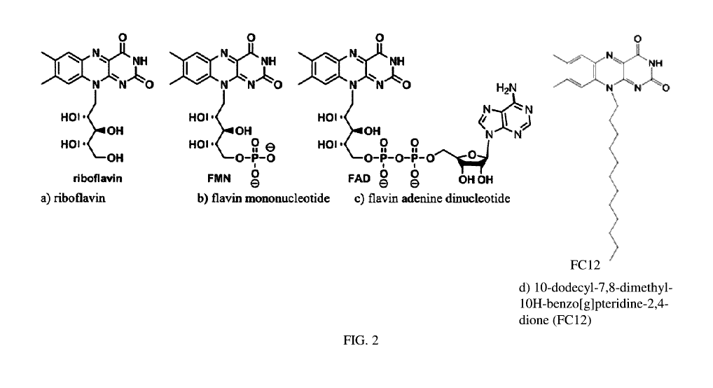

In one embodiment, the flavin-containing molecule reversibly combines with the carbon nanotube to produce a flavin-SWNT nanocomposite. Exemplary flavin moieties include naturally occurring riboflavin, flavin mononucleotides (FMN), and flavin adenine dinucleotide (FAD), the chemical structures of which are shown in FIG. 2. In an embodiment, the molecules that comprise flavin moieties can be flavin derivatives, e.g., 10-dodecyl-7,8-dimethyl-10H-benzo[g]pteridine-2,4-dione (FC12). A flavin moiety with ring numbering is shown in Formula (1) below:

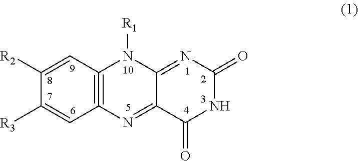

The flavin derivatives are generally obtained by reacting substituents onto the flavin moiety at R₁, R₂, or R₃. In one embodiment, the substituent can be a side chain that can be linear or branched and can comprise polar and/or non-polar moieties that facilitate solubility of the flavin-SWNT nanocomposite in a variety of polar and non-polar solvents. As can be seen in Formula (1), the substituents can be reacted to the flavin moiety at the 7, 8, and the 10 positions. Preparation of flavin moieties and their helical formation on nanotubes is described in U.S. Pat. No. 8,193,430, the disclosure of which is incorporated herein in its entirety.

By changing the end groups and pendent groups on the flavin-containing molecules, the carbon nanotubes can be dispersed in various media (e.g., water, acetone, tetrahydrofuran, ethyl acetate, N,N-dimethylformamide, pyridine, and the like). Spectroscopic (UV-Vis-NIR, photoluminescence, and X-ray diffraction) and transmission electron microscopy (TEM) results detailed below support the formation of such charge-transfer flavin-based helix on the side-walls of single wall carbon nanotubes. Circular dichroism (CD) spectroscopy indicates that flavin-containing molecules (e.g., those comprising flavin mononucleotides) can combine with carbon nanotubes to form the nanocomposite in a manner that is effective to facilitate a separation of carbon nanotubes based on chirality and handedness and that can produce enrichment of certain species of (n,m)-SWNTs in the nanocomposite.

When solutions that contain the nanocomposite are freeze-dried, the dried sample exhibits a crystalline matrix with a long-range order of flavin mononucleotide crystals. In addition, the nanocomposites formed reflect the sensitivity of the flavin helix to the diameter and electronic structure of the SWNTs that they organize on, and as a result, afford diameter- and electrical conductivity-based enrichment avenues, respectively. Last but not least, these nanocomposites are photo responsive, which also can be used for the separation of some types of carbon nanotubes from others based upon chirality and handedness.

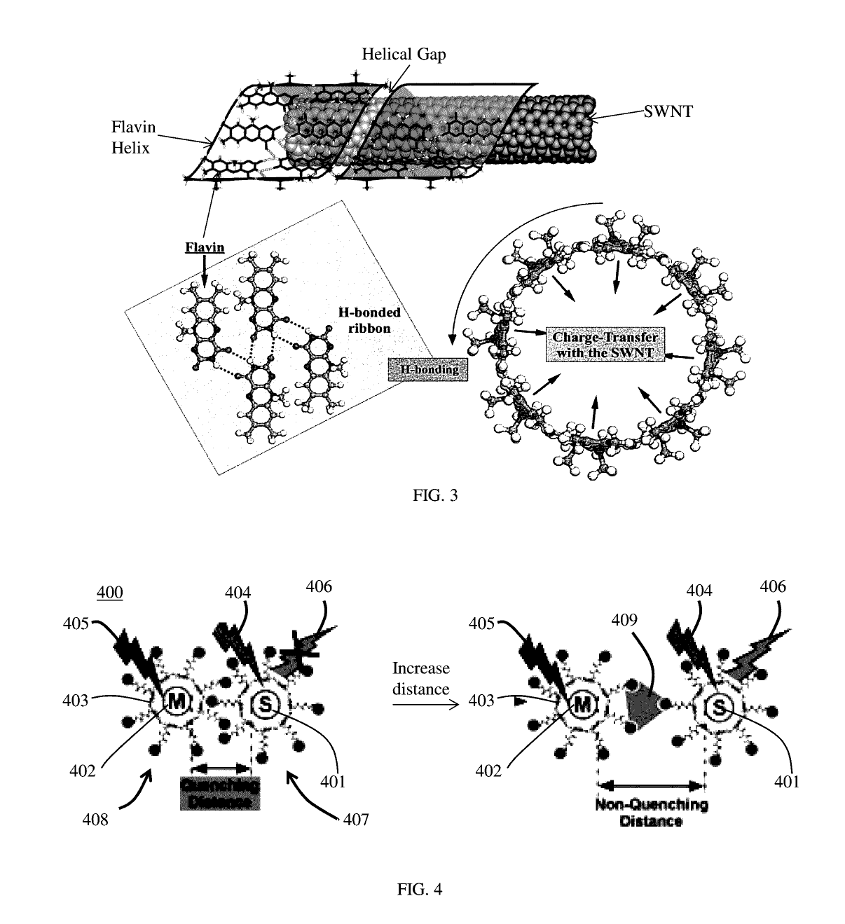

As noted above, the flavin derivatives are generally obtained by reacting substituents onto the flavin moiety. The flavin mononucleotide or d-ribityl alloxazine (RA) can be substituted with substituents at various positions and brought into contact with carbon nanotubes to form the nanocomposite. As noted above, the flavin-containing molecule can undergo hydrogen-bonding and charge-transfer interactions with each other via the polar end groups and pendent groups as shown in FIG. 3. The ability to form hydrogen bonding and charge-transfer interactions with each other permits the formation of extended flavin mononucleotide and d-ribityl alloxazine structures that form helical structures with tight helical wrapping of the nanotube as shown in the top of FIG. 3.

In one embodiment, the flavin mononucleotide or d-ribityl alloxazine (RA) can be substituted in a variety of positions to obtain molecules that can wrap helically around the carbon nanotubes to form the nanocomposite. These substituents permit the nanocomposite to be suspended in organic media as well as in aqueous media. The substituent can be linear or branched alkyl chains, in which a number of carbon atoms can be from about 1 to about 200, specifically about 2 to about 150 and more specifically about 3 to about 50. These alkyl substituents permit the flavin-containing molecule to be soluble in an organic solvent. In one embodiment, these alkyl substituents can be terminated with polar groups. In addition, polar groups may be added as pendent groups on to the alkyl chains. Examples of these polar groups are hydroxyl groups, amine groups, carboxylic acid groups, aldehydecarboxylic acid groups, phenylene groups, thiol groups, acrylate groups, styryl groups, norbornene groups, amino acid side groups, and the like. In one embodiment, a branched alkyl substituent can be terminated with a hydroxyl group, an amine group, a carboxylic acid group, a phenylene group, a thiol group, or the like.

In an embodiment, the flavin derivatives comprise ethylene oxide sidechains, where a number of ethylene oxide is ranging from 1 to 200. The ethylene oxide sidechain can be terminated hydroxyl, amine, carboxylic acid, phenylene, and thiol group.

In an embodiment, the substituent comprises a complex chiral center such as R- or L-ribityl, R- or L-ribityl phosphate, R- and L-ribityl diphosphatic adenine, R- or L-arabityl, R- or L-arabityl phosphate, R- and L-arabityl diphosphatic adenine, R- or L-xylityl, R- or L-xylityl phosphate, R- and L-xylityl diphosphatic adenine, R- or L-xylityl, R- or L-xylityl phosphate, R- and L-xylityl diphosphatic adenine, R- or L-lyxytyl, R- or L-lyxytyl phosphate, and R- and L-lyxytyl diphosphatic adenine.

In an embodiment, the flavin mononucleotide or d-ribityl alloxazine (RA) can be substituted in the 7, 8, or 10 positions. The substitutions can be the same or different and are generally independent of each other. In one embodiment, the flavin mononucleotide or d-ribityl alloxazine can be substituted by alkyl moieties and olefins Examples of alkyl moieties are methyl, ethyl, propyl, isopropyl, butyl, pentyl, hexyl, heptyl, octyl, nonyl, decyl, undecyl, dodecyl, pentadecyl, hexadecyl heptadecyl, and the like. As noted above, the alkyl moieties and olefins can be bonded to other polar species at the chain ends or in pendent positions.

In one embodiment, the substituent for the 7, 8, or 10 positions can be an organic polymer. The organic polymer can be an oligomer, a homopolymer, a copolymer, a block copolymer, an alternating block copolymer, a random polymer, a random copolymer, a random block copolymer, a graft copolymer, a star block copolymer, a dendrimer, or the like, or a combination thereof. The organic polymer can be an amorphous polymer or a semi-crystalline polymer that facilitates solubility of the flavin-nanotube composite in a solvent. In an exemplary embodiment, it is desirable for the substituent to comprise a crystallizable polymer. In another exemplary embodiment, it is desirable for the polymer to be a liquid crystalline polymer, specifically a lyotropic liquid crystalline polymer. In yet another exemplary embodiment, the polymers, specifically the liquid crystalline polymers, can be copolymerized with a soft flexible polymeric block. The soft flexible polymeric blocks generally have a glass transition temperature that is lower than room temperature.

Examples of suitable polymers that can be used as substituents are polyolefins, polyacetals, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polyimidazopyrrolones, polypyrrolidines, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, polysiloxanes, cellulose, nucleic acids, polypeptides, proteinaceous polymers, polysaccharides, chitosans, or the like, or a combination thereof.

Examples of polymers that are used in the soft blocks are elastomers such as polyethylene glycols, polydimethylsiloxanes, polybutadienes, polyisoprenes, polyolefins, nitrile rubbers, or the like, or a combination thereof.

In an exemplary embodiment, the nitrogen atom of the isoalloxazine ring in the 10 position can be substituted by polymers that comprise nucleic acids, protein nucleic acids, peptides, (meth)acrylic acids, saccharides, chitosans, hyaluronic acids, vinyl ethers, vinyl chlorides, acrylonitriles, vinyl alcohols, styrenes, (meth)acrylates, norbornenes, copolymers of divinyl styrene and norbornadiene, pyrroles, thiophenes, anilines, phenylenes phenylene-vinylenes, phenylene-acetylenes, esters, amides, imides, carbonates, urethanes, ureas phenols, oxadiazoles, oxazolines, thiazoles, furans, cyclopentadienes, hydroxyquinones, azides, acetylenes, benzoxazoles, benzothiazinophenothiazines, benzothiazoles, pyrazinoquinoxalines, pyromellitimides, quinoxalines, benzimidazoles, oxindoles, oxoisoindolines, dioxoisoindolines, triazines, pyridazines, piperazines, pyridines, piperidines, triazoles, pyrazoles, pyrrolidines, carboranes, oxabicyclononanes, dibenzofurans, phthalides, acetals, anhydrides, and the like with a degree of polymerization of about 1 to about 200 with a degree of polymerization between 1 and 200. In one embodiment, the substitution can be conducted using hydroxyl, amine, aldehyde, carboxylic acid, ether, carbonyl, ester, acid anhydride, nitro, amide, vinyl, acetylene, diacetylene, and acid halide side groups. In addition, as noted above, the polymer substituents can be reacted to end-groups comprising hydroxyl, amine, aldehyde, carboxylic acid, ether, carbonyl, ester, acid anhydride, nitro, amide, vinyl, acetylene, diacetylene, acid halides, and the like, or a combination thereof. Substituents that comprise nitrogen and phosphorus can also be used.

In one embodiment, the substituent to the flavin moiety can be a nanocrystal. The nanocrystal can comprise a metal or a semiconductor. In one embodiment, the nanocrystal can comprise nanoparticles having a very narrow particle size distribution. In other words, the polydispersity index of the nanoparticles may be about 1 to about 1.5, if desired. Examples of nanoparticles are gold (e.g., Au₆₄) silver, cadmium selenide, cadmium telluride, zinc sulfide, silicon, silica, germanium, gallium nitride (GaN), gallium phosphoride (GaP), gallium arsenide (GaAs), and the like.

In another embodiment, the substituent can be a low molecular weight organic moiety having a molecular weight of less than or equal to about 1,000 grams per mole. The low molecular weight organic moiety can be a crystallizable drug. The crystallizable drug can be dexamethasone, doxorubicin, methadone, morphine, and the like.

In another embodiment, the substituent can be a therapeutic and pharmaceutic biologically active agents including anti-proliferative/antimitotic agents including natural products such as vinca alkaloids (e.g., vinblastine, vincristine, and vinorelbine), paclitaxel, epidipodophyllotoxins (e.g., etoposide, teniposide), antibiotics (e.g., dactinomycin, actinomycin D, daunorubicin, doxorubicin and idarubicin), anthracyclines, mitoxantrone, bleomycins, plicamycin, mithramycin and mitomycin, enzymes (L-asparaginase, which systemically metabolizes L-asparagine and deprives cells which do not have the capacity to synthesize their own asparagine), antiplatelet agents such as G(GP) IIb/IIIa inhibitors and vitronectin receptor antagonists, anti-proliferative/antimitotic alkylating agents such as nitrogen mustards (e.g., mechlorethamine, cyclophosphamide and analogs, melphalan, chlorambucil), ethylenimines and methylmelamines (e.g., hexamethylmelamine and thiotepa), alkyl sulfonates, busulfan, nitrosoureas (e.g., carmustine (BCNU) and analogs, streptozocin), trazenes-dacarbazinine (DTIC), anti-proliferative/antimitotic antimetabolites such as folic acid analogs (e.g., methotrexate), pyrimidine analogs (e.g., fluorouracil, floxuridine, cytarabine), purine analogs and related inhibitors (e.g., mercaptopurine, thioguanine, pentostatin and 2-chlorodeoxyadenosine {cladribine}), platinum coordination complexes (e.g., cisplatin, carboplatin), procarbazine, hydroxyurea, mitotane, aminoglutethimide, hormones (e.g., estrogen), anti-coagulants (e.g., heparin, synthetic heparin salts, and other inhibitors of thrombin), fibrinolytic agents (e.g., tissue plasminogen activator, streptokinase and urokinase), aspirin, dipyridamole, ticlopidine, clopidogrel, abciximab, antimigratory, antisecretory (e.g., breveldin), anti-inflammatory: such as adrenocortical steroids (e.g., cortisol, cortisone, fludrocortisone, prednisone, prednisolone, 6α-methylprednisolone, triamcinolone, betamethasone, and dexamethasone), non-steroidal agents (e.g., salicylic acid derivatives such as aspirin, para-aminophenol derivatives such as acetominophen, indole and indene acetic acids (e.g., indomethacin, sulindac, etodalac), hetero aryl acetic acids (e.g., tolmetin, diclofenac, ketorolac), arylpropionic acids (e.g., ibuprofen and derivatives), anthranilic acids (e.g., mefenamic acid, meclofenamic acid), enolic acids (e.g., piroxicam, tenoxicam, phenylbutazone, oxyphenthatrazone), nabumetone, gold compounds (e.g., auranofin, aurothioglucose, gold sodium thiomalate), immunosuppressives (e.g., cyclosporine, tacrolimus (FK-506), sirolimus (e.g., rapamycin, azathioprine, mycophenolate mofetil)), angiogenic agents such as vascular endothelial growth factor (VEGF), fibroblast growth factor (FGF), angiotensin receptor blockers, nitric oxide donors, anti-sense oligionucleotides and combinations thereof, cell cycle inhibitors, mTOR inhibitors, and growth factor receptor signal transduction kinase inhibitors, retenoids, cyclin/CDK inhibitors, HMG co-enzyme reductase inhibitors (statins), or protease inhibitors. The substituents can also include time-release drugs and agents.

In one embodiment, the substituent is a protein, the protein being crystallizable. The protein can be an oxidoreductase, a transferace, a hydrolase, a lyase, an isomerase, a ligase, a protein, an ion channel protein, or a visual protein. Examples of oxidoreductase are myogrobin, horseradish peroxidase, glucose oxidase, glucose dehydrogenase, lactate oxidase, alcohol dehydrogenase, Cytochrome P450, or the like, or a combination thereof.

In one embodiment, the substituent is a nucleic acid oligomer, where the nucleic acid oligomer binds onto a polymeric single stranded nucleic acid with complementary bases. In yet another embodiment, the nucleic acid oligomers binds onto a polymeric double stranded nucleic acid through Hoogstein base pairing.

In an exemplary embodiment, the nitrogen atom of the isoalloxazine ring in the 10 position the flavin mononucleotide or d-ribityl alloxazine (RA) can be substituted by alkyl moieties and olefins. Examples of alkyl moieties are listed above. The alkyl moieties and olefins can be bonded to other polar species at the chain ends or in pendent positions. In one embodiment, the nitrogen atom of the isoalloxazine ring in the 10 position can be substituted by the polymers listed above that have a degree of polymerization of about 1 to about 200. As noted above, the substituent in the 10 position can comprise hydroxyl, amine, aldehyde, carboxylic acid, ether, carbonyl, ester, acid anhydride, nitro, amide, vinyl, acetylene, diacetylene, acid halide side groups, or a combination thereof. In an exemplary embodiment, the substituent in the fifth position of the flavin mononucleotide or d-ribityl alloxazine comprises a hydrocarbon, nitrogen, or phosphorus. The substituents can include all of the aforementioned molecules and moieties, dyes, drugs, liquid crystalline polymers, and the like.

In another exemplary embodiment, the substituent in the seventh and eighth positions for the flavin mononucleotide or d-ribityl alloxazine are independent of each other and can be the same or different. Examples of substituents for the seventh and the eighth position are those that comprise ethyl, propyl, isopropyl, butyl, chloride, bromide, fluoride, iodide, nitrile, hydroxyl, methyl ester, alkene, alkyne, amine, amide, nitro, thiol, thioether, and the like.

In an embodiment, an enriched nanocomposite can be prepared such that a plurality of nanocomposites are enriched with (n,m)-SWNTs that include an (8,6)-SWNT, (7,7)-SWNT, or a combination thereof. Moreover, as discussed below, the enriched nanocomposite is substantially free of all other (n,m)-SWNTs but (n,m)-SWNTs selected from the (8,6)-SWNT and (7,7)-SWNT, (n,m)-SWNTs without a flavin moiety disposed thereon, bundled nanotubes, and other impurities. According to an embodiment, the enriched nanocomposites can have one enantiomer of (n,m)-SWNT present in an amount greater amount greater than a second enantiomer, e.g., a minus (M) enantiomer can be present in a greater amount than a plus (P) enantiomer of the (n,m)-SWNT. That is, the M-(8,6)-SWNT enantiomer can be present in an amount greater than the P-(8,6)-SWNT enantiomer in the enriched nanocomposite.

Since the helix of flavin moieties disposed on the (n,m)-SWNT is sensitive to the handedness of the underlying SWNT carbon lattice, the helix can reflect a preferred handedness. In an embodiment, the handedness of the helix is opposite to that of the SWNT. Also, one handedness of the helix can be present in the enriched nanocomposite in an amount greater than its opposite handedness. Here again, the M and P nomenclature respectively represent minus and plus handedness of the helix. In a particular embodiment, the nanocomposite comprises a P-handed helix disposed on an M-handed SWNT, an M-handed helix disposed on a P-handed SWNT, or a combination thereof, and more particularly a P-handed helix disposed on an M-(8,6)-SWNT, an M-handed helix disposed on a P-(8,6)-SWNT, or a combination thereof.

In an embodiment, the helix of flavin moieties disposed around the (n,m)-SWNT in the nanocomposite can have surface defects, e.g., a gap between portions of the helix such that the helix is discontinuous. In such a discontinuous region of the helix, a flavin moiety can be present between the gap but unattached (i.e., not bonded) to the flavin moieties in the helix. Similarly, the discontinuity can be free of flavin moieties or other surface adsorbates on the (n,m)-SWNT such that a portion of the (n,m)-SWNT is exposed in the discontinuous region of the helix. According to an embodiment, the nanocomposite can be annealed to remove the discontinuity. In this manner, the mobility of the flavin moieties disposed on the (n,m)-SWNT is increased, and a continuous length of the helix of flavin moieties is increased by eliminating the discontinuity from the helix. In another embodiment, flavin moieties can be adsorbed onto the exposed portion of the (n,m)-SWNT to fill the gap and bond to helix in order to extend the continuous length of the helix on the (n,m)-SWNT. As a result, the continuous length of the helix of flavin moieties can be from 10 nanometers (nm) to greater than 1 micrometer (μm), specifically 20 nm to 900 nm, and more specifically 50 nm to 800 nm, based on a longitudinal distance along the (n,m)-SWNT. Advantageously, the nanocomposite, having been subjected to annealing to remove the discontinuity can have a greater thermal stability than that of the nanocomposite before annealing. Thus, the temperature at which the helix of flavin moieties dissociates from the (n,m)-SWNT can be controllably increased upon annealing by removal of the discontinuities or otherwise lengthening the continuous length of the helix. Furthermore, the annealed nanocomposite suppresses formation of bundles of the annealed nanocomposite with (n,m)-SWNTs, nanocomposites, or a combination thereof.

The self-assembled helix of flavin moieties has a high degree of the order on the (n,m)-SWNT in the nanocomposite, especially after removal of discontinuities and lengthening of the helix. Due to long range order, the helix can have a repeat pattern, which can be determined, e.g., by X-ray diffraction or electron scattering. Depending on the flavin moieties in the helix and the specific (n,m)-SWNT, the repeat pattern of the helix can be, e.g., from 1.5 nm to 3.5 nm, and specifically 2 nm to 3.2 nm. In one embodiment, the helix is composed of FMN disposed around an (8,6)-SWNT and has a repeat patter of 2.5 nm as determined by X-ray diffraction.

Due to the interaction of the helix of the flavin moieties with the electronic structure of the SWNT, the stability of the nanocomposite depends on the minimization of the free energy of the helix with the SWNT. In the nanocomposite herein, the helix is extensively formed over the surface of the SWNT. Since the helix tightly wraps around the SWNT in a certain helical configuration, e.g., a P-handed or M-handed helix, the carbon lattice of the SWNT varies from its typical largely straight, cylindrical configuration. To minimize the free energy of the nanocomposite, the SWNT twists along its length to accommodate the overlayer of the helix of flavin moieties. Thus, the SWNT has a writhe whose periodicity depends upon and supports particular geometries of the helix of flavin moieties. Therefore, in some embodiments, the nanocomposite has a coiled structure along its length where the helix of flavin moieties wraps around the SWNT such that the nanocomposite has a writhe defined by that of the SWNT and a corresponding writhe periodicity. Such nanocomposites are referred to herein as superhelix nanocomposites.

The period of the writhe (hereinafter referred to as writhe periodicity) along a longitudinal length of the (n,m)-SWNT in the superhelix nanocomposite can be determined by, e.g., transmission electron microscopy. The writhe periodicity can vary and can depend upon associations with other superhelix nanocomposites as discussed below for braided nanocomposites.

The helix of flavin moieties has a groove interposed between adjacent turns of the helix on the SWNT, and the helix can be arranged in various geometries to achieve a given number of flavin moieties per turn of the helix. In an embodiment, the helix is arranged in an 8/1 configuration on the SWNT such that 8 flavin moieties in the helix wrap around the SWNT per turn of the helix. According to an embodiment, the helix has an 8/1 configuration incommensurate with a 7/1 helical configuration of the SWNT. Other geometries of the helix of flavin moieties and helical configuration of the SWNT are contemplated for the superhelix nanocomposite.

In another embodiment, a braided nanocomposite includes a plurality of superhelix nanocomposites that are reversibly combined in a braided helical configuration. In the braided nanocomposite, the helices of flavin moieties of adjacent superhelix nanocomposites interact to form the overall braided helical configuration. In an embodiment, adjacent superhelix nanocomposites have interdigitated helices, e.g., in a knobs-into-holes configuration. Here, in an example of two adjacent superhelix nanocomposites in a braided nanocomposite, a groove in a helix of a first superhelix nanocomposite engages the flavin moieties in the helix of a second superhelix nanocomposite.

Such braided nanocomposites can be formed in response to a concentration of the superhelix nanocomposites being greater than a critical concentration for forming the braided nanocomposite. Thus, for example, a dilute solution of superhelix nanocomposites may contain relatively few or no braided nanocomposites. Increasing the concentration of such a solution above the critical concentration leads to formation of the braided nanocomposite.

The number of superhelix nanocomposites in the braided nanocomposite can be from 2 to 10 superhelix nanocomposites, specifically 2 to 5 superhelix nanocomposites, and more specifically from 2 to 3 superhelix nanocomposites. In contrast, to certain materials that can form superhelix structures (e.g., certain proteins), the number of the superhelix nanocomposites in the braided nanocomposite is self-limited. That is, the braided nanocomposite does not sustain uncontrolled growth superhelix nanocomposites by bundling or aggregation.

Further, the composition of the braided nanocomposite is governed by the constituent superhelix nanocomposites used to form the braided nanocomposite. As such, the (n,m)-SWNTs of the plurality of superhelix nanocomposites in the braided nanocomposite can be an (n,m)-met-SWNT, (n,m)-sem-SWNT, or a combination thereof. In one embodiment, the (n,m)-met-SWNT is a (7,7)-SWNT, and the (n,m)-sem-SWNT is an (8,6)-SWNT. Again, one enantiomer of a specific (n,m)-SWNT can be present in an amount greater than the other enantiomer in the superhelix nanocomposites in the braided nanocomposite, and the plurality of superhelix nanocomposites can have an excess of one handedness of the (n,m)-SWNTs, helix of flavin moieties, or a combination thereof. The handedness of the (n,m)-SWNTs can be different helix of flavin moieties for the superhelix nanocomposites in the braided nanocomposite.

As noted above, once the plurality of superhelix nanocomposites are reversibly combined to form the braided nanocomposite, the plurality of superhelix nanocomposites can dissociate in response to a change in a condition, including superhelix nanocomposite concentration, temperature, pH, displacement of the flavin moiety from the helix in the nanocomposite, or a combination thereof.

In an embodiment, the distance between adjacent (n,m)-SWNTs of the plurality of superhelix nanocomposites in the braided nanocomposite can be controlled by, e.g., adjustment of the substituent on the flavin moieties of the helix. As used herein, “distance between adjacent (n,m)-SWNTs of the nanocomposites” refers to a distance between the walls of the nanotubes of the adjacent (n,m)-SWNTs. According to an embodiment, the distance between adjacent (n,m)-SWNTs of the plurality of superhelix nanocomposites in the braided nanocomposite is from 0.2 nm to 2 nm, specifically 0.4 nm to 1.8 nm, and more specifically 0.6 nm to 1.6 nm. Given that the number of superhelix nanocomposites as well as the distance between adjacent (n,m)-SWNTs can be controlled in the braided nanocomposite, it follows that an average diameter of the braided nanocomposite can therefore be controlled. In an embodiment, the average diameter of the braided nanocomposite is from 2 nm to 6 nm, and specifically 2.5 nm to 5 nm. As used herein, “diameter of the braided nanocomposite” refers to a diameter of a transverse cross-section averaged over the length of a braided nanocomposite and, if applicable, the number of braided nanocomposites in a plurality of braided nanocomposites.

As noted above, the writhe periodicity of the superhelix nanocomposite and the braided nanocomposite can be determined by, e.g., transmission electron microscopy. The writhe periodicity can vary and can depend upon the number of superhelix nanocomposites in the braided nanocomposite. In an embodiment, the braided nanocomposite has a writhe periodicity from 10 nm to 520 nm. In a particular embodiment, the braided nanocomposite includes two superhelix nanocomposites and has a writhe periodicity from 10 to 230 nm. In another embodiment, braided nanocomposite includes three superhelix nanocomposites and has a writhe periodicity from 10 to 100 nm.

Thus, in one embodiment, a braided nanocomposite includes a plurality of superhelix nanocomposites reversibly combined in a braided helical configuration. Each of the superhelix nanocomposites includes an (n,m)-SWNT), a plurality of flavin moieties disposed in a helix which is self-assembled around the (n,m)-SWNT, and a writhe formed by coiling of the (n,m)-SWNT. The plurality of superhelix nanocomposites reversibly combines to form the braided nanocomposite in response to a concentration of the superhelix nanocomposites being greater than a critical concentration for forming the braided nanocomposite. The (n,m)-SWNT includes an (n,m)-sem-SWNT, (n,m)-met-SWNT, or a combination thereof such that the helix has a continuous length along a longitudinal length of the (n,m)-SWNT. The continuous length of the helix can be as long as the entire longitudinal length of the (n,m)-SWNT, specifically from more than 50 nm, more specifically from 50 nm to 2000 nm, and even more specifically from 200 nm to 700 nm, based on a longitudinal distance along the (n,m)-SWNT. Here, the plurality of superhelix nanocomposites can reversibly combine in response to a change in a condition that includes superhelix nanocomposite concentration, temperature, pH, displacement of flavin moieties from the helix in the superhelix nanocomposite (such as dissociation, removal, substitution of the flavin moieties), or a combination thereof.

The nanocomposite, nanocomposite superhelix, and braided nanocomposite herein can be made in various ways. In one embodiment, the nanocomposite can be produced by disposing (n,m)-SWNTs and flavin moieties together in a medium. Here, the flavin moieties can adsorb onto the surface of the (n,m)-SWNTs to form a distribution of species of (n,m)-SWNTs coated with flavin moieties. To selectively enrich specific (n,m) species of (n,m)-SWNTs in the large (n,m)-distribution of the nanocomposite, liquid-liquid extraction can be used for selected-chirality nanotube purification. This process provides, e.g., facile extraction of such species such as (8,6)- and (7,7)-SWNTs achieved by the liquid-liquid extraction at a biphasic (e.g., oil/water) interface. In an embodiment, a solvent (e.g., an organic solvent such as an oil) either strengthens or disrupts the coating of flavin moieties around an aqueous-dispersed flavin coated (n,m)-SWNT. The (n,m)-SWNTs that retain and thus strengthen their association with the helix of flavin moieties maintain their dispersion ability in the aqueous phase, while those (n,m)-SWNTs with disrupted helices precipitate at the oil/water interface.

Hence, according to an embodiment, a method for enriching an initial concentration of (8,6)-SWNTs, (7,7)-SWNTs, or a combination thereof, from a plurality of (n,m)-SWNTs, includes dispersing the plurality of (n,m)-SWNTs in a first medium comprising flavin moieties under conditions effective for the flavin moieties to self-assemble in a wrapped pattern around the (n,m)-SWNTs, to form a nanocomposite; contacting the nanocomposite with a second medium that is immiscible with the first medium under conditions effective to enrich, in the first medium, the concentration of an (8,6)-SWNT nanocomposite, (7,7)-SWNT nanocomposite, or a combination thereof relative to the initial concentration in the plurality of (n,m)-SWNTs; and separating the first medium from the second medium. The wrapped pattern can be, e.g., a helix wrapped around the (n,m)-SWNT. In an embodiment, the nanocomposite is a tubular, quasi-epitaxial nanocomposite that results from self-assembly of the flavin moieties in an ordered helix wrapping around the (n,m)-SWNT. Excess flavin can be removed from the medium surrounding the nanocomposite, and the flavin moieties in the helix can be subjected to chemical functionalization to introduce a substituent onto the flavin moieties. The substituent can be one of the above-mentioned substituents. It will be appreciated that chemical functionalization does not alter the nanocomposite structure or any component thereof.

As used herein, “immiscible” refers to a second medium that is slightly soluble, sparingly soluble, or not soluble with the first medium such that when combined with the first medium, the first medium and second medium form two phases separated by an interface therebetween.

As a result of π-π interactions between the flavin moieties (i.e., flavin-containing molecules) with the (n,m)-SWNTs and also as a result of hydrogen bonding and charge transfer interactions between the flavin moieties themselves, the flavin moieties form a tight helix around the (n,m)-SWNTs. The substituents generally are disposed radially outwards from the (n,m)-SWNTs and can facilitate solvation of the nanocomposite in an appropriate medium such as a solvent. According to an embodiment, the flavin moieties include flavin mononucleotide, flavin adenine dinucleotide, FC12 (10-dodecyl-7, 8-dimethyl-10H-benzo[g]pteridine-2,4-dione), riboflavin, or a combination thereof. The flavin moieties can also be substituted with an above-mentioned substituent, e.g., a complex chiral center.

It is to be noted that dispersing the (n,m)-SWNTs or flavin moieties can be conducted in a solution or in a melt and can be conducted in a device that uses shear force, extensional force, compressive force, ultrasonic energy, electromagnetic energy, thermal energy, or a combination thereof and can be conducted in processing equipment wherein the aforementioned forces are exerted by a single screw, multiple screws, intermeshing co-rotating or counter rotating screws, non-intermeshing co-rotating or counter rotating screws, reciprocating screws, screws with pins, barrels with pins, rolls, rams, helical rotors, sound energy, or a combination thereof. Dispersing, e.g., blending, or mixing, involving the aforementioned forces or forms of energy may be conducted in machines such as sonicators, single or multiple screw extruders, Buss kneader, roll mills, molding machines such as injection molding machines, vacuum forming machines, blow molding machines, or the like, or a combination thereof. It is to be noted that single or multiple screw extruders, Buss kneader, roll mills, molding machines such as injection molding machines, vacuum forming machines, and blow molding machine can be combined with sonicators to provide the enriched nanocomposite.

The method of enrichment of the nanocomposite also includes separating the first medium and second medium that includes partitioning the first medium from the second medium to form an interface at a boundary between the first medium and second medium. Separating causes segregation of the various nanocomposites between the first medium and the second medium such that, advantageously, the method also includes removing from the first medium nanocomposites comprising all other (n,m)-SWNTs but (n,m)-SWNTs selected from, e.g., the (8,6)-SWNT and (7,7)-SWNT, (n,m)-SWNTs without a flavin moiety disposed thereon, bundled nanotubes, and other impurities, which are collectively referred to as contaminants. The removal can be precipitating those compounds at the interface between the first medium and the second medium. After separation of the first medium and second medium and removal of contaminants from the first medium, e.g., by precipitation at the interface of the first and second media, the first fluid contains the enriched nanocomposites. Besides precipitation from the first medium by liquid-liquid extraction, the contaminants can be removed from the first medium in various ways such as filtration, fractional filtration, size-exclusion based chromatography, density gradient centrifuging, chromatography, anionic chromatography, silica gel columns, electrophoresis, dielectrophoresis, or a combination thereof. In an embodiment, centrifuging can be conducted at a centrifugal speed from 2 g (where g is the acceleration due to gravity) to 500,000 g, specifically about 10 g to about 200,000 g, and more specifically about 100 g to about 50,000 g

This separation methodology is efficient, facile, rapid, and selective for nanocomposites having certain (n,m)-SWNTs. Without wishing to be bound by theory and as noted above, the nanocomposite that is formed depends upon the interactions between the flavin-containing molecule with the (n,m)-SWNTs and with each other. The interactions result in the preferential formation of nanocomposites based on the length, diameter, handedness, chirality, and electrical conductivity characteristics (e.g., metallicity or semiconductivity) of the (n,m)-SWNTs. For species of (n,m)-SWNTs that interact more strongly with flavin moieties, the resulting helix of flavin moieties will synergistically associate more strongly with the (n,m)-SWNTs than when the flavin moieties interact less strongly with the (n,m)-SWNTs. This property can be used to control the particular species that are enriched in the enrichment method herein. In particular, the choice of the second medium can affect the nanocomposite by increasing or decreasing the strength of the interaction of the helix of flavin moieties with the (n,m)-SWNT. For weakly interacting helix-SWNT nanocomposites, the helix can dissociate from the (n,m)-SWNT and be precipitated at the interface between the first medium and the second medium. In contrast, for strongly interacting helix-SWNT nanocomposites, the helix of flavin moieties remains disposed around the (n,m)-SWNT (and the interaction can even be made stronger) and these are not precipitated. Instead, these nanocomposites remain dispersed in the first medium since the flavin moieties aid in solubilization of the nanocomposite in the first medium. As a result, certain (n,m)-SWNTs are selectively enriched in the first medium.

Subsequent to separating the first medium and the second medium to form the enriched nanocomposite, the precipitated contaminants and the second fluid can be discarded, leaving the first medium containing the enriched nanocomposite. The enriched nanocomposite can be isolated from the first medium by various separation methods, which can be the same as or different from the removal of the contaminants from the first medium. The separation of the enriched nanocomposite from the first medium can be conducted by processes involving centrifugation, filtration, size-exclusion based chromatography, density gradient centrifugation, anionic chromatography, silica gel columns, dielectrophoresis, lyophilization, and the like. In this manner, the enriched nanocomposite is collected from the first medium after separating the first medium and the second medium.

The first and second media, which are typically solvents, can be liquid aprotic polar solvents, polar protic solvents, non-polar solvents, or a combination thereof. Due to the immiscibility of the first medium and the second medium used in forming the enriched nanocomposite, it is contemplated that when the first medium is an aqueous medium, the second medium can be, for example, a non-polar solvent.

Liquid aprotic polar solvents such as water, propylene carbonate, ethylene carbonate, butyrolactone, acetonitrile, benzonitrile, nitromethane, nitrobenzene, sulfolane, dimethylformamide, N-methylpyrrolidone, or the like, or a combination thereof are generally desirable. Polar protic solvents such as, but not limited to, water, methanol, acetonitrile, nitromethane, ethanol, propanol, isopropanol, butanol, or the like, or a combination thereof may be used. Other non-polar solvents such as benzene, toluene, ortho-xylene, meta-xylene, para-xylene, chlorobenzene, methylene chloride, chloroform, carbon tetrachloride, hexane, diethyl ether, tetrahydrofuran, or the like, or a combination thereof may also be used. Exemplary solvents include water, alcohols such as methanol, ethanol, and the like, acetonitrile, butyrolactone, propylene carbonate, ethylene carbonate, ethylene glycol, diglyme, triglyme, tetraglyme, nitromethane, nitrobenzene, benzonitrile, methylene chloride, chloroform and other solvents, as well as high viscosity solvents like glucose, molten sugars, and various oligomers, pre-polymers and polymers.

In one embodiment, the first medium is an aqueous medium containing a polar solvent, e.g., water, and the second medium is an organic solvent such as cyclohexanone, ethyl acetate, and the like. In contacting the nanocomposite in the first medium with the second medium before partitioning the first medium from the second medium, the second medium can destabilize and cause partial or complete dissociation of those helices that weakly interact with their underlying (n,m)-SWNTs. Consequently these weakly interacting composites will be precipitated out of the first medium. As a result of the destabilization and separating the first and second medium, the enrichment method herein enriches a first enantiomer of particular (n,m)-SWNTs in the enriched nanocomposite. In an embodiment, nanocomposites having (n,m)-SWNTs that include the (8,6)-SWNT, (7,7)-SWNT, or a combination thereof are included in the enriched nanocomposite. Here, the first medium can enhance the stability of the flavin moieties on the (n,m)-SWNTs comprising the (8,6)-SWNT, (7,7)-SWNT, or a combination thereof. Moreover, the second medium can decrease the affinity of flavin moieties on all but (8,6)- or (7,7)-SWNTs such that nanocomposites (or SWNTs without a helix of flavin moieties disposed thereon) precipitate from the first medium.

Further, the enrichment produces a preferential amount of one enantiomer over the other enantiomer for certain chiral (n,m)-SWNTS. In an embodiment, the enriched nanocomposite has a first enantiomer of the (8,6)-SWNT in an amount greater than a second enantiomer of the (8,6)-SWNT. In some embodiments, the first enantiomer of the (8,6)-SWNT is M-(8,6)-SWNT. In addition to the selection of particular (n,m)-SWNTs in the enriched nanocomposite, the enrichment produces a preferred handedness of the helix of flavin moieties such that a first handedness of the helix is present in the enriched nanocomposite in an amount greater than a second handedness. In an embodiment, the first handedness is plus (P)-handedness, i.e., a P-helix. According to an embodiment, the handedness of the helix is different than that of the (n,m)-SWNT on which the helix is disposed. In one embodiment, a (P)-helix of flavin moieties is disposed around an (M)-(n,m)-sem-SWNT, specifically an (M)-(8,6)-SWNT. In another embodiment, an (M)-helix of flavin moieties is disposed on the (P)-(8,6)-SWNT.

After enrichment, the nanocomposite comprising the helix disposed on the (n,m)-SWNT, e.g., the enriched nanocomposite, can be treated with a reagent that displaces (e.g., by removal or substitution) the flavin moiety from a portion of the carbon nanotube. Examples of such reagents are surfactants. The surfactants can be anionic surfactants, cationic surfactants, zwitterionic surfactants, and the like. The reagent competes with self-assembly of the flavin moieties on the nanotube and perturbs the helical wrapping around the nanotubes. Examples of suitable surfactants that can displace flavin moieties are sodium dodecyl sulfate (SDS), sodium dodecylbenzenesulfonate (SDBS), sodium cholate (SC), deoxyribonucleic acid, block copolymers, and the like. Selective replacement of the flavin moieties on a nanotube using a surfactant such as SDBS or SC can be performed. In an embodiment, the FMN in the helix is displaced by the SC. In an embodiment, the addition of the reagent can stabilize certain helical patterns more than other to increase the stability of a given chirality(ies) of (n,m)-SWNTs. Such replacement of flavin moieties with the surfactant can aid in determining the identity of the enriched (n,m)-SWNTs in the enriched nanocomposite as well as allowing titration experiments to investigate size distributions in braided nanocomposites as discussed below. The replacement of flavin moieties by the surfactant can occur according to the affinity constant (Kₐ) of the flavin-wrapping for each (n,m) chirality species. Therefore, in an embodiment, the introduction of a controlled amount of a reagent can induce controlled aggregation of SWNTs subjected to replacement or removal of their flavin helix. This causes flocculation and precipitation of the reagent-exchanged SWNTs, while flavin-wrapped SWNTs with a higher Kₐ can remain intact. Thus, in a plurality of nanocomposites, replacement of the flavin moieties in a helix can be selective even for enriched nanocomposites.

The nanocomposite that includes the helix of flavin moieties disposed on the (n,m)-SWNT can be subjected to a process that removes defects in the helix. In an embodiment, a method for removing a surface defect in a nanocomposite includes disposing a nanocomposite in a first medium. It is contemplated that a plurality of surface defects, which are the same or different, can occur along the surface of the (n,m)-SWNT. The nanocomposite can include an (n,m)-single wall carbon nanotube ((n,m)-SWNT); and a plurality of flavin moieties disposed on the (n,m)-SWNT, a portion of the plurality of flavin moieties being arranged in a helix on the (n,m)-SWNT. The nanocomposite is contacted with a second medium, and the plurality of flavin moieties disposed on the (n,m)-SWNT is annealed to remove the surface defect from the nanocomposite to form an annealed nanocomposite. As noted above, the surface defect can be, e.g., a gap between portions of the helix such that the helix is discontinuous. In such a discontinuous region of the helix, a flavin moiety can be present in the gap but unattached (i.e., not bonded) to the flavin moieties in the helix. Similarly, the discontinuity can be free of flavin moieties or other surface adsorbates on the (n,m)-SWNT such that a portion of the (n,m)-SWNT is exposed in the discontinuous region of the helix. Annealing removes the discontinuity. In this manner, the mobility of the flavin moieties disposed on the (n,m)-SWNT is increased, and a continuous length of the helix of flavin moieties is increased by eliminating the discontinuity from the helix. In an embodiment, annealing comprises lowering a melting temperature of the plurality of flavin moieties disposed on the (n,m)-SWNT to a reduced melting temperature. Lowering the melting temperature to the reduced melting temperature can be accomplished by the second medium. The first and second media can be one of those discussed above. According to an embodiment the first medium is an aqueous medium, and the second medium is an organic solvent such a cyclohexanone, ethyl acetate, and the like. To aid in removing the defect, annealing can include heating the nanocomposite to a temperature effective to mobilize the flavin moieties disposed on the (n,m)-SWNT, the temperature being based on the reduced melting temperature. The reduced melting temperature can depend on the strength of the interaction between the helix and the (n,m)-SWNT and can be from 30° C. to 100° C., specifically 40° C. to 90° C., and more specifically 50° C. to 80° C.

Annealing produces a nanocomposite with an enhanced continuous length of the helix on the SWNT, which can be from 10 nanometers (nm) to greater than 1 micrometer (μm), specifically 20 nm to 900 nm, and more specifically 50 nm to 800 nm, based on a longitudinal distance along the (n,m)-SWNT.

In an embodiment, the annealed nanocomposites are coiled along a longitudinal length of the nanocomposite such that they form a superhelix nanocomposite comprising a writhe. The writhe repeats on the length of the superhelix nanocomposite. Combining a plurality of superhelix nanocomposites forms a braided nanocomposite. In the braided nanocomposite, the superhelix nanocomposites reversibly combine in a braided helical configuration. Here, in addition to the writhe in the braided nanocomposite, each superhelix nanocomposite maintains its own writhe due to the coiled structure of the superhelix nanocomposite. According to an embodiment, the plurality of superhelix nanocomposites reversibly dissociate in response to a change in a condition comprising superhelix nanocomposite concentration, temperature, pH, displacement of the flavin moiety from the helix in the nanocomposite, or a combination thereof. Here, the distance between adjacent (n,m)-SWNTs of the braided nanocomposites increases as the superhelix nanocomposites dissociate. A subsequent change in the condition that caused dissociation also can restore the braided nanocomposite by recombining the superhelix nanocomposites. Thus, a method for producing a superhelix nanocomposite includes forming a nanocomposite (which comprises an (n,m)-SWNT); an ordered, long-range helix comprising flavin moieties helically wrapped around the (n,m)-SWNT; and quasi-epitaxial interactions between the inner lattice of the (n,m)-SWNT and the outer lattice of the ordered, long-range flavin helix that exerts internal stress to the tubular nanocomposite); and inducing coiling of the (n,m)-SWNT to form a superhelix nanocomposite that includes a writhe. Without wishing to be bound by theory, it is believed that the quasi-epitaxial interactions induce the coiling of the (n,m)-SWNT to form the writhe. In this way, the superhelix nanocomposite has a tubular, quasi-epitaxial structure.

The nanocomposites herein (i.e., the enriched, annealed, superhelix, and braided nanocomposites) have favorable mechanical, chemical, and photophysical properties due to incorporation of the (n,m)-SWNTs. Moreover, the helix of flavin moieties disposed on the (n,m)-SWNT can tune these properties such that the nanocomposite has unique and beneficial properties. The methods herein are scalable and allow for the selective enrichment of, e.g., one semiconducting SWNT species (i.e., (8,6)-SWNT) and one metallic SWNT species (i.e., (7,7)-SWNT). In addition, the sem-SWNT specie can have a single handedness: P-(8,6)-SWNT or M-(8,6)-SWNT). It should be noted that (6,8)-SWNT is identical to P-(8,6)-SWNT. The methods herein also provide for the formation of a highly-ordered, defect-free flavin helix around these nanotubes. Various flavins, both substituted and unsubstituted can be used, and they produce a stable monolayer coverage of the flavin (e.g., FMN). Excess flavin (e.g., FMN) can be removed from the medium surrounding the nanocomposite to permit numerous functionalization schemes, while retaining the flavin helix-SWNT nanocomposite structure.

Nanocomposite superhelicity (i.e., a writhe (a spiral twist) along the longitudinal dimension (i.e., length) of the SWNT) is induced by the highly-ordered flavin helix on the SWNT. The resulting nanocomposite (and thus SWNT) superhelicity (a) allows for controllable nanocomposite braiding, where the distance between adjacent SWNTs is controllable, and (b) prevents uncontrollable SWNT aggregation that promotes and limits the size of braided nanocomposite and number of superhelix nanocomposites in the braided nanocomposite to, e.g., double and triple braids. The nanocomposites herein provide well-defined helical and superhelical grooves around SWNTs, which (a) control braiding of sem-SWNTs and met-SWNTs into double and triple braids, and (b) afford controlled groove binding of biological and synthetic entities onto enantio-pure, chiral nanocomposites (e.g., braided nanocomposites) with a periodicity along the length of the nanocomposite from nanometer to submicron distances.

The nanocomposite further has size uniformity that enables uniform formation of braided nanocomposites between a sem-SWNT (e.g., an (8,6)-SWNT) and a met-SWNT (e.g., a (7,7)-SWNT). The braided nanocomposite is formed without development of epitaxial strain, and the distance of the two SWNT species (sem-SWNT and met-SWNT in a combination such as sem-sem, sem-met, met-met, sem-sem-met, sem-met-met, and the like) can be controlled via lattice interpenetration between interacting helices. By changing the substituent of the flavin moiety in the helix, the distance can be controlled at the molecular level, e.g., from angstrom (A) to nanometer distances.

It will be appreciated by one skilled in the art that metallic and semiconducting SWNTs used in the nanocomposites herein have photophysical properties such that these SWNTs can absorb energy via electronic transitions when subjected to irradiation of various wavelengths. The absorption can include absorption of wavelengths in the ultraviolet (UV), visible (Vis), and near infrared (NIR) regions of the electromagnetic spectrum. For nanocomposites, the helix of flavin moieties on the (n,m)-SWNT will affect the wavelength at which the SWNT has a maximum in its absorption spectrum. Thus a red shift in absorption can occur due to the presence of the helix on the SWNT. Furthermore, while sem-SWNTs emit photoluminescent emission after excitation, met-SWNTs do not emit photoluminescent emission. As shown in FIG. 4, in the braided nanocomposite 400 that includes a combination of a sem-SWNT (S) 401 and met-SWNT (M) 402, the presence of the met-SWNT 402 can affect the photoluminescent properties of the sem-SWNT 401 via the Fano effect. Here, the presence of the flavin helices 403 around met-SWNT 402 and sem-SWNT 401 can prevent the direct contact of the two SWNTs species 401, 402. Direct contact between a met-SWNT 402 and sem-SWNT 401 causes photoluminescent emission quenching and broadening of electronic transitions. Since the distance of the SWNTs 401, 402 in the braided nanocomposite 400 can be controlled, non-radiative pathways due to mirror-induced charges of the bandgap of, e.g., the (8,6)-sem-SWNT 401 by an adjacent (7,7)-met-SWNT 402 (which causes carrier trapping and photoluminescent quenching), can be prevented along the metallic continuum. However, quenching can occur in a wavelength vicinity of a particular transition, e.g., the E^{M}₁₁ absorption transition of the (7,7)-SWNT 402 that peaks at about 500 nm. Therefore, in an embodiment, the braided nanocomposite 400 including a met-SWNT 402 and sem-SWNT 401 can exhibit photoluminescent emission (PLE) that is subject to quenching when the E^{M}₁₁ transition is excited but otherwise maintains PLE at other excitation wavelengths. Consequently, upon dissociation or increasing distance separation of the sem-SWNT 401 and met-SWNT 402 superhelix nanocomposites in the braided nanocomposite 400, individual (8,6)-sem-SWNTs can recover their PLE even though the E^{M}₁₁ transition is excited.

The Fano effect can be used such that, in an embodiment, a method for inducing photoluminescent emission in the superhelix nanocomposite includes irradiating a medium comprising a plurality of superhelix nanocomposites 407, 408 with primary radiation comprising an excitation wavelength 404, irradiating the medium with secondary radiation comprising a combination of the excitation wavelength 404 and a quenching wavelength 405, and collecting photoluminescent emission 406 from the first superhelix nanocomposite 407. The superhelix nanocomposite can include an (n,m)-SWNT, a helix 403 comprising a plurality of flavin moieties wrapped around the (n,m)-SWNT, and a writhe formed in response to coiling of the (n,m)-SWNT. In some embodiments, the plurality of superhelix nanocomposites 407, 408 includes a first superhelix nanocomposite 407 in which the (n,m)-SWNT is an (n,m)-sem-SWNT 401 and a second superhelix nanocomposite 408 in which the (n,m)-SWNT is an (n,m)-met-SWNT 402, or a combination thereof. The method also includes reversibly forming a braided nanocomposite 400 in response to a concentration of the superhelix nanocomposites 407, 408 being greater than a critical concentration for forming the braided nanocomposite 400. The braided nanocomposite 400 includes two or more superhelix nanocomposites 407, 408 reversibly arranged in a braided helical configuration. Therefore, the method includes inducing controlled photoluminescent quenching of the emission of a superhelical braided nanocomposite. Moreover, the (n,m)-SWNTs can have a helix that includes a plurality of flavin moieties helically wrapped around each (n,m)-SWNT, with the (n,m)-met-SWNT being separated from the (n,m)-sem-SWNT by, e.g., two interdigitated flavin helices. The two interdigitated flavin helices correspond to the individual helices that wrap around each (n,m)-SWNT so that, in the superhelix nanocomposite, adjacent (n,m)-SWNTs that are braided together are in contact via their flavin helices, and the major and minor grooves of the flavin helices interdigitate.

The excitation wavelength 404 excites an excitation channel in the first superhelix nanocomposite 407, and the quenching wavelength 405 excites a quenching channel in the second superhelix nanocomposite 408. The photoluminescent emission 406 is emitted by the first superhelix nanocomposite 407 in response to irradiating the medium with the primary radiation. It should be noted that PLE is emitted from all (n,m)-sem-SWNTs 401 upon excitation with the primary radiation (i.e., in the absence of irradiation with the quenching wavelength 405). Moreover, the photoluminescent emission 406 is emitted by the first superhelix nanocomposite 407 in response to irradiating the medium with the secondary radiation for the first superhelix nanocomposite 407 that is not in the braided nanocomposite. Further, the photoluminescent emission 406 is emitted by the first superhelix nanocomposite 407 in the braided nanocomposite 400 in response to irradiating the medium with the secondary radiation, wherein the second superhelix nanocomposite 408 is not in the braided nanocomposite 400. However, the photoluminescent emission 406 is quenched before being emitted by the (n,m)-sem-SWNT of the first superhelix nanocomposite 407 in the braided nanocomposite 400 in response to irradiating the medium with the secondary radiation when the second superhelix nanocomposite 408 is in the braided nanocomposite 400, and the photoluminescent emission 406 is recovered from being quenched in response to increasing a distance between the first superhelix nanocomposite 407 and the second superhelix nanocomposite 408 in the braided nanocomposite 400. Increasing the distance between the between the first superhelix nanocomposite 407 and the second superhelix nanocomposite 408 in the braided nanocomposite 400 includes a change in a condition comprising superhelix nanocomposite concentration, temperature, pH, displacement (e.g., removal) of the flavin moieties from the helix 403 in the nanocomposite, dissociation of the flavin helix 403 from the superhelix nanocomposite 407, 408, or a combination thereof. Using the photoluminescent emission 406 and Fano effect of the braided nanocomposite 400, an amount of the first superhelix nanocomposite 407 in the braided nanocomposite 400 can be determined. Additionally, the first 407 and second 408 superhelix nanocomposites can be used as internal calibration standards.

Again with reference to FIG. 4, introduction of an analyte 409 (e.g., due to an increase in pH) causes superhelix nanocomposite (407, 408) dissociation or dilation that increases the photoluminescent emission 406 from the (n,m)-sem-SWNT 401. Unlike fluorescence resonance energy transfer (FRET) detection where a single excitation wavelength is typically used, the Fano effect combines two input wavelengths, excitation 404 and quenching 405 wavelengths, to respectively excite the excitation and quenching channels of the sem-SWNT 401 and met-SWNT 402.

In one embodiment, an excitation wavelength, e.g., 720 nm, excites an excitation channel (the E^{S}₂₂ transition) in the (8,6)-sem-SWNT to produce photoluminescent emission at about 1200 nm. A quenching wavelength, e.g., 500 nm, excites a quenching channel (the E^{M}₁₁ transition) in the (7,7)-met-SWNT to quench the 1200 nm photoluminescent emission of the (8,6)-sem-SWNT. Such dual excitation provides unique spatial and temporal specificity for advanced sensing techniques such as confocal microscopy, pump-probe wave mixing techniques, coherence interferometry, and the like. Internal calibration is of great importance in bio-sensing, especially for an in vivo environment, where calibration charts typically do not apply or are unavailable.

In an embodiment, these unique properties of the Fano effect of the braided nanocomposite herein can be used in, e.g., confocal microscopy. The braided nanocomposite includes an (n,m)-sem-SWNT and (n,m)-met SWNT. Here, optical density at 500 nm can be measured, e.g., by optical absorption to provide the local concentration of the (7,7)-met-SWNTs. The optical density at 720 nm is then measured to provide the local concentration of the (8,6)-sem-SWNTs. Then, confocal photoluminescent emission at 1200 nm is measured to provide the photoluminescent intensity of the focused voxel (i.e., a focus volume in confocal microscopy). Using the acquired optical densities at 500 nm and 720 nm and photoluminescent emission enables reconstruction of a 3D image by (i) exciting at 720 nm where photoluminescence intensity arises from all (8,6)-sem-SWNTs within the voxel and (ii) exciting the voxel with dual wavelengths of 720 nm and 500 nm, where the photoluminescent intensity arises from only (8,6)-sem-SWNTs in the voxel that are not braided with (7,7)-met-SWNTs. The difference between (i) and (ii) provides the amount of (8,6)-sem-SWNTs braided with (7,7)-met-SWNTs in the braided nanocomposite within the voxel. By averaging this concentration (number of (8,6)-sem-SWNTs per volume in the voxel) through all voxels within the optical paths of the 500 nm and 720 nm wavelengths in the confocal geometry, the averaged photoluminescent emission can be correlated with the optical densities determined at 500 nm and 720 nm to obtain quantitative results that do not need external calibration standards. Furthermore, differentiation of photoluminescent emission at 1200 nm and 1157 nm can provide complete optical assignment respectively of braided (1200 nm) and unbraided (1157 nm) FMN-wrapped (8,6)-SWNTs. Application of this methodology can be used, e.g., to directly assess pH in organelles in cell or tissue cultures or even through thin portions of tissue, e.g., tissue of the ear, ear drums, and other thin skin or membranes, etc.

The versatility of the braided nanocomposite can be implemented in diverse applications. The Fano effect of the nanocomposites herein can be used for in vitro and in vivo immunosensing assays (e.g., antibody-antigen). Antibodies typically have low concentrations in biological samples, from nanomolar (nM=10⁻⁹ M) to femtomolar (fM=10⁻¹⁵ M) or even attomolar (10⁻¹⁸ M), zeptomolar (10⁻²¹ M), or yoctomolar (10⁻²⁴ M) concentrations. Detection of these low concentrations requires amplification methodologies to increase a signal arising from the analyte to within detection limits of analytical equipment, e.g., a spectrometer. Typical detection limits for analytical instruments are from micromolar (10⁻⁶ M) to sub-nanomolar (>10⁻⁹ M) for optical and fluorescence spectroscopy, respectively. In an embodiment, the nanocomposites herein can be used for amplification that also provides internal calibration capabilities (discussed above).

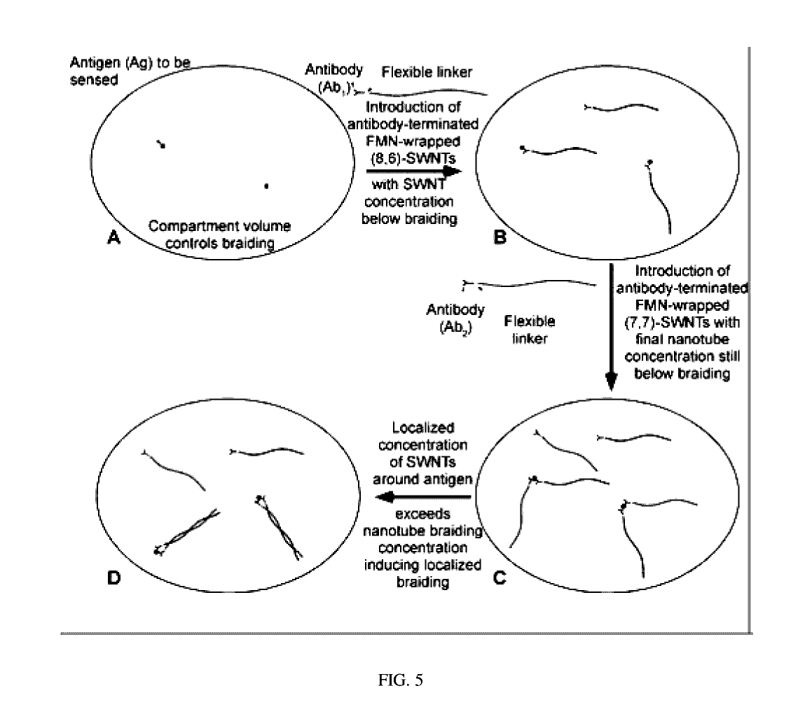

According to an embodiment, the braided nanocomposite can be used to sense an analyte, for example, an antigen. With reference to FIG. 5, a method for sensing the antigen 500 includes disposing the antigen 500 in the medium 501 prior to disposing superhelix nanocomposites 502, 503 in the medium 501, disposing the first superhelix nanocomposite 502 of the braided nanocomposite 504 in the medium 501 such that a concentration of the superhelix nanocomposites 502, 503 is below the critical concentration for forming the braided nanocomposite 504. The first superhelix nanocomposite 502 further includes a first antibody 505 disposed at a primary terminus of the first superhelix nanocomposite 502 and a flexible member 506 interposed between the first antibody 505 and the primary terminus of the first superhelix nanocomposite 502. The method of sensing also includes binding the first antibody 505 to the antigen 500, disposing the second superhelix nanocomposite 503 in the medium 501, such that the concentration of the superhelix nanocomposites 502, 503 is below the critical concentration for forming the braided nanocomposite 504. The second superhelix nanocomposite 503 further includes a second antibody 507 disposed at a primary terminus of the second superhelix nanocomposite 503 and a flexible member 508 interposed between the second antibody 507 and the primary terminus of the second superhelix nanocomposite 503. The second antibody 507 binds to the antigen 500.

Binding the first antibody 505 and the second antibody 507 to the antigen 500 increases the concentration of the superhelix nanocomposites 502, 503 proximate to the antigen 500 to be greater than the critical concentration for forming the braided nanocomposite 504 such that the first superhelix nanocomposite 502 and the second superhelix nanocomposite 503 form the braided nanocomposite 504 with the braided nanocomposite 504 bound to the antigen 500 via the first antibody 505 and the second antibody 507. Thereafter, photoluminescent emission is collected from the medium 501 to sense the antigen 500. In an embodiment, an intensity of emission of the antigen 500 is less than an intensity of the photoluminescent emission from irradiating the medium 501 with the primary radiation, an amount of photoluminescent emission lost due to quenching of the photoluminescent emission from the first superhelix nanocomposite 502 by the second superhelix nanocomposite 503 in the braided nanocomposite 504 from irradiating the medium 501 with the secondary radiation, or a combination thereof.

According to the method for sensing the antigen, the large aspect ratio (length over diameter) of nanocomposites of SWNTs (e.g., 10⁴ to 10⁵ for an FMN-wrapped SWNT) provides optical amplification due to its optical cross-section (i.e., optical absorptivity or photofluorescent emission intensity for (8,6)-sem-SWNTs). The ability of typical antigens to bind more than one antibody is used to increase the local concentration of nanocomposites proximate to the antigen. Although complex biological environments (e.g., plasma, etc.) provides a challenging spectroscopic matrix, the photoluminescent emission intensity at 1200 nm and 1157 nm is used to distinguish the amounts of braided and unbraided flavin (e.g., FMN)-wrapped (8,6)-SWNTs. Furthermore, without resorting to heterogeneous removal, pre-concentration, or other amplification strategies typically employed in immunosensing; the amount of the antigen can be determined using dual excitation (excitation and quenching wavelengths) by exploiting the Fano effect of the braided nanocomposite. Additionally, introduction of a flexible member (e.g., a flexible oligomer or functional group) between the antibody and the superhelix nanocomposite prevent steric hindrance so that braided nanocomposites can form. Since all (n,m)-SWNTs used in the method are spectroscopically assigned, independent calibration is not necessary. Further, analysis of living tissues and cells can be performed without damage because the nanocomposites herein can be introduced locally and subjected to endocytosis by various cellular mechanisms.

Additional signal amplification for immunosensing can be acquired by introducing DNA sticky ends at a terminus of the superhelix nanocomposite. As a result, the length of the braided nanocomposite is extended to increase its optical density. This can be achieved for DNA-terminated superhelix nanocomposites having, e.g., FMN as the flavin moieties in the helix disposed on (8,6)- and (7,7)-SWNTs.

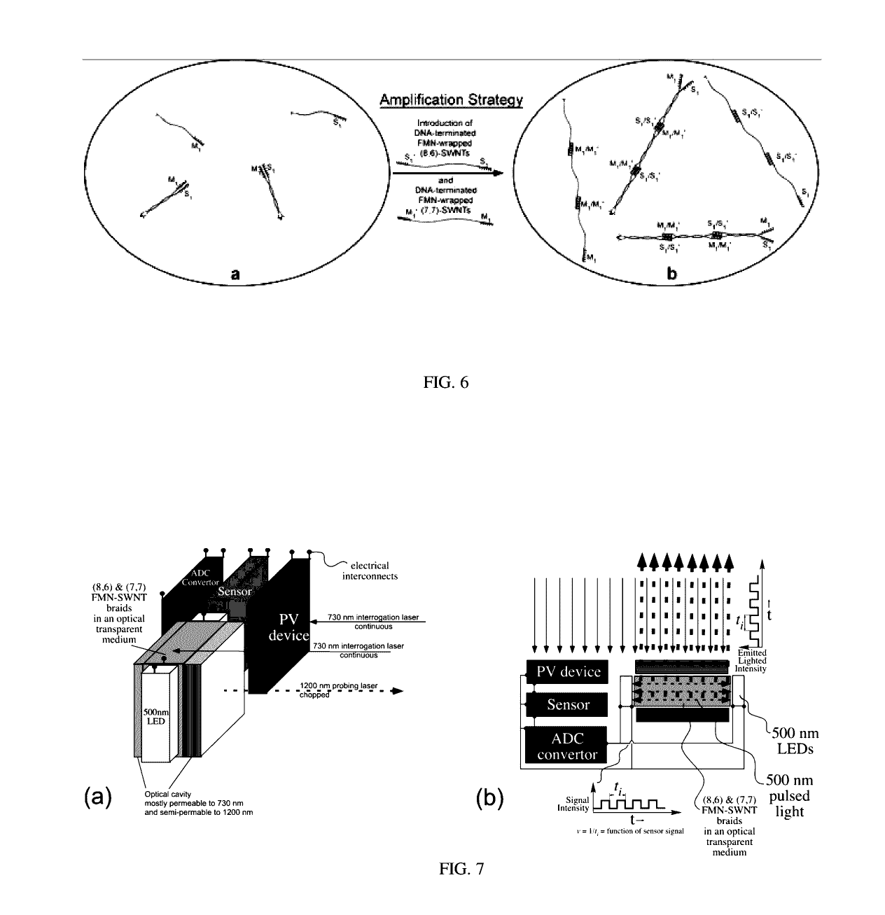

With reference to FIG. 6, the first superhelix nanocomposite 502 further includes a first DNA sticky end 600 disposed at a terminus opposing the primary terminus of the first superhelix nanocomposite 502, and the second superhelix nanocomposite 503 further includes a second DNA sticky end 601 disposed at a terminus opposing the primary terminus of the second superhelix nanocomposite. Sensing the antigen 500 is amplified by disposing a third superhelix nanocomposite 602 in the medium 501. The third superhelix nanocomposite 602 includes a first DNA sticky end disposed 600 at a primary terminus of the third superhelix nanocomposite 602 and a third DNA sticky end 603 disposed at a terminus opposing the primary terminus of the third superhelix nanocomposite 602. A fourth superhelix nanocomposite 604 is disposed in the medium 501. The fourth superhelix nanocomposite 604 includes a second DNA sticky end 601 disposed at a primary terminus of the fourth superhelix nanocomposite 604 and a fourth DNA sticky end 605 disposed at a terminus opposing the primary terminus of the fourth superhelix nanocomposite 604. The third DNA sticky end 603 includes a DNA sequence that is complementary to that of the first DNA sticky end 600. The fourth DNA sticky end 605 includes a DNA sequence that is complementary to that of the second DNA sticky end 601. The (n,m)-SWNT of the third superhelix nanocomposite 602 is an (n,m)-sem-SWNT, and the (n,m)-SWNT of the fourth superhelix nanocomposite 604 is an (n,m)-met-SWNT. Here, the superhelix nanocomposite concentration in the medium 501 is less than the critical concentration for forming the braided nanocomposite except proximate to the antigen 500 with the antibodies 505, 507 attached thereto.

The third superhelix nanocomposite 602 emits the photoluminescent emission in response to irradiation with the primary radiation (comprising the excitation wavelength), and the fourth superhelix nanocomposite 604 quenches the photoluminescent emission from the third superhelix nanocomposite 602 in response to irradiation of the medium 501 with the secondary radiation (comprising the excitation wavelength and quenching wavelength) when the third 602 and fourth 604 superhelix nanocomposites are adjacently disposed in a braided helical configuration. Here, the primary radiation excites (n,m)-sem-SWNTs, and (n,m)-met-SWNTs quench the photoluminescent emission by the (n,m)-sem-SWNTs upon irradiation of the medium 501 by the secondary radiation. According to the method, amplifying the sensing of the antigen includes attaching the third superhelix nanocomposite 602 to the antigen 500 by binding the third DNA sticky end 603 of the third superhelix nanocomposite 602 to the first DNA sticky end 600 of the first superhelix nanocomposite 502 having a first antibody 505 bound to the antigen 500. Also, the fourth superhelix nanocomposite 604 is attached to the antigen 500 by binding the fourth DNA sticky end 605 of the fourth superhelix nanocomposite 604 to the second DNA sticky end 601 of the second superhelix nanocomposite 503 having a second antibody 507 bound to the antigen 500, thereby extending the braided nanocomposite 504 comprising the first 502 and second 503 superhelix nanocomposites (which are bound to the antigen 500) by forming a braided helical configuration between the third 603 and fourth 604 superhelix nanocomposites upon attaching the third 603 and fourth 604 superhelix nanocomposites to the antigen 500. In this manner, extending the braided nanocomposite 504 bound to the antigen 500 by attaching the third 603 and fourth 604 superhelix nanocomposites to the antigen 500 increases the intensity of the photoluminescent emission in response to irradiating the medium 501 with the primary radiation and increases the amount of quenching of the photoluminescent emission in response to irradiating the medium 501 with the secondary radiation to amplify the sensing of the antigen 500.

According to an embodiment, the excitation wavelength is from 300 nm to 400 nm, 650 nm to 750 nm, or a combination thereof. The quenching wavelength is from 480 nm to 520 nm, and the photoluminescent emission is from 1150 nm to 1250 nm.

The nanocomposites herein can be combined into articles having a particular shape that can be used in a myriad of applications such as nanoelectronics, nanoplasmonics, remote sensing, nanomedicine, and the like. Articles that include the nanocomposites herein can combine plasmonic effects of met-SWNTs together with a density of spectroscopically active electronic transitions of the sem-SWNTs and met-SWNTs in the submicron wavelength region of the electromagnetic spectrum. Devices formed from the nanocomposites can exploit optical, magnetic, plasmonic, chiral, and non-linear behavior of the nanocomposites in such arrangements as nanoscaffolds and nanoprobes.

Remotely sensing a variety of responses (e.g., those associated with a concentration of a chemical), amplitude of a given response (e.g., displacement such as vibration), radioactivity, and the like has implications in applications such as structural, environmental, defense, and medical applications. Many remote sensors require electrical power, which can complicate construction of a nanosensor and can increase its size, complexity, and cost. On-board power supplies, e.g., a battery, can have finite power and lifetime. According to an embodiment, a nanosensor system is not restricted by such power limitations. As shown in FIG. 7, the nanosensor includes a power unit 701, to generate power, a sensor 702 configured to generate an electrical signal in response to sensing an event and is electrically connected to the power unit 701, and a signal converter 703 to receive and convert the electrical signal into an electrical pulse and to output the electrical pulse. The signal converter 703 is electrically connected to the power unit 701 and sensor 702. The nanosensor system 700 also includes an optical modulator 704 that includes a light source 705 to output a quenching wavelength 706 that is modulated between an on-state and an off-state at a frequency of the electrical pulse from the signal converter 703 wherein the light source 705 is electrically connected to the power unit 701 and signal converter 703. The optical modulator 704 further includes an optical cavity 707 that includes a cavity 708 to contain a composition comprising a braided nanocomposite and a plurality of walls 709 disposed about the cavity 708 to transmit radiation, wherein the radiation can be back radiation.

The power unit 701 can include a photovoltaic device, battery, motor, or a combination thereof. In some embodiments, the power unit 701 is the photovoltaic device that generates power in response to receiving an excitation wavelength 710 from an external light source (not shown). The electrical signal generated by the sensor 702 can be an analog signal that is proportional to an amplitude of the event. Exemplary events include temperature, pH, displacement, pressure, position, actuation, flow, concentration, or a combination thereof. The signal converter 703 converts the analog signal, and the electrical pulse is a digital pulse. The light source 705 can be, for example, a laser, light emitting diode, flash lamp, or a combination thereof.

Here, the braided nanocomposite includes a plurality of superhelix nanocomposites such as a first superhelix nanocomposite in which its (n,m)-SWNT is an (n,m)-sem-SWNT and a second superhelix nanocomposite in which its (n,m)-SWNT is an (n,m)-met-SWNT. In an embodiment, the braided nanocomposite includes an (n,m)-sem-SWNT with a helix comprising a plurality of flavin moieties wrapped around the (n,m)-sem-SWNT and an (n,m)-met-SWNT with a helix comprising a plurality of flavin moieties wrapped around the (n,m)-met-SWNT arranged such that the (n,m)-sem-SWNT is separated from the (n,m)-met-SWNT via two-interdigitated flavin helices. The braided nanocomposite has a Fano effect such that the excitation wavelength 710 excites an excitation channel in the (n,m)-sem-SWNT of the first superhelix nanocomposite, and a quenching wavelength 706 from the light source 705 excites a quenching channel in the (n,m)-met-SWNT of the second superhelix nanocomposite. The optical cavity 707 is configured to transmit a modulated photoluminescent emission 711 comprising photoluminescent emission that is emitted by the (n,m)-met-SWNT in response to irradiation by the excitation wavelength 710 and that is modulated in response to irradiation by the quenching wavelength 706 such that the photoluminescent emission is emitted when the quenching wavelength 706 has the off-state and is quenched when the quenching wavelength 706 has the on-state. In this manner, a time of occurrence of the event that is sensed by the sensor 702 is encoded in the modulated photoluminescent emission 711 and corresponds to the photoluminescent emission being quenched. In some embodiments the excitation wavelength 710 is a continuous wave but can also be modulated. Further, the excitation wavelength 710 can be from 300 nm to 400 nm, 650 nm to 750 nm, or a combination thereof, and the quenching wavelength 706 can be from 480 nm to 520 nm. Moreover, the modulated photoluminescent emission 711 can be from 1150 nm to 1250 nm. The photoluminescent emission of the (n,m)-sem-SWNT can be recovered from being quenched by, for example, increasing a distance between the first superhelix nanocomposite and the second superhelix nanocomposite in the braided nanocomposite within the optical cavity 707. Additionally, the composition disposed in the optical cavity 707 further can include a medium that is optically transparent to the excitation wavelength 710 and modulated photoluminescent wavelength 711.

The nanosensor system 701 therefore can be used as a highly miniaturized remote sensor. The remote operation of the nanosensor system 701 is based on powering it with a remote light source, e.g., a laser source, that provides the excitation wavelength 710 to excite the (n,m)-sem-SWNT, e.g., a (8,6)-SWNT, of the first superhelix nanocomposite that is braided with a flavin- (e.g., FMN) wrapped (n,m)-met-SWNT, e.g., a (7,7)-SWNT. The radiation from the remote laser can be split, e.g., by a beam splitter, so that a portion of radiation from the remote laser excites the (8,6)-SWNT in the optical cavity 707, and another portion irradiates the adjacent power unit 701, e.g., a photovoltaic (PV) device. The PV device produces power that is used to power the sensor 702 and the signal converter 703, e.g., an analog to digital convertor (ADC). The resulting signal (derived from any type of source) from the sensor 702 is received by the ADC 703 and is transformed in current pulses. The frequency of the current pulses is proportional to the signal intensity detected at the sensor 702. The current pulses from the ADC 703 are sent to and received by the light source 705, e.g., a 500 nm LED. The LED 705 produces pulsed light, i.e., the quenching wavelength 706, having the same frequency as the input current pulses received from the ADC 703. This 500 nm light 706 converts the photoluminescent emission of the (8,6)-SWNTs into pulsed emission (i.e., modulated photoluminescent emission 711) of the same frequency. Consequently, the signal from the sensor 702 is converted into modulated photoluminescent emission 711, whose frequency is proportional to the signal from the sensor 702. Furthermore, the optical cavity 707 permits the modulated photoluminescent emission 711 to be returned to the remote light source, thus bypassing any remote wiring.

The nanocomposite herein can be used in an electrical component such as a nanotransistor, nanoactuator, structural nanoprobe, and the like.

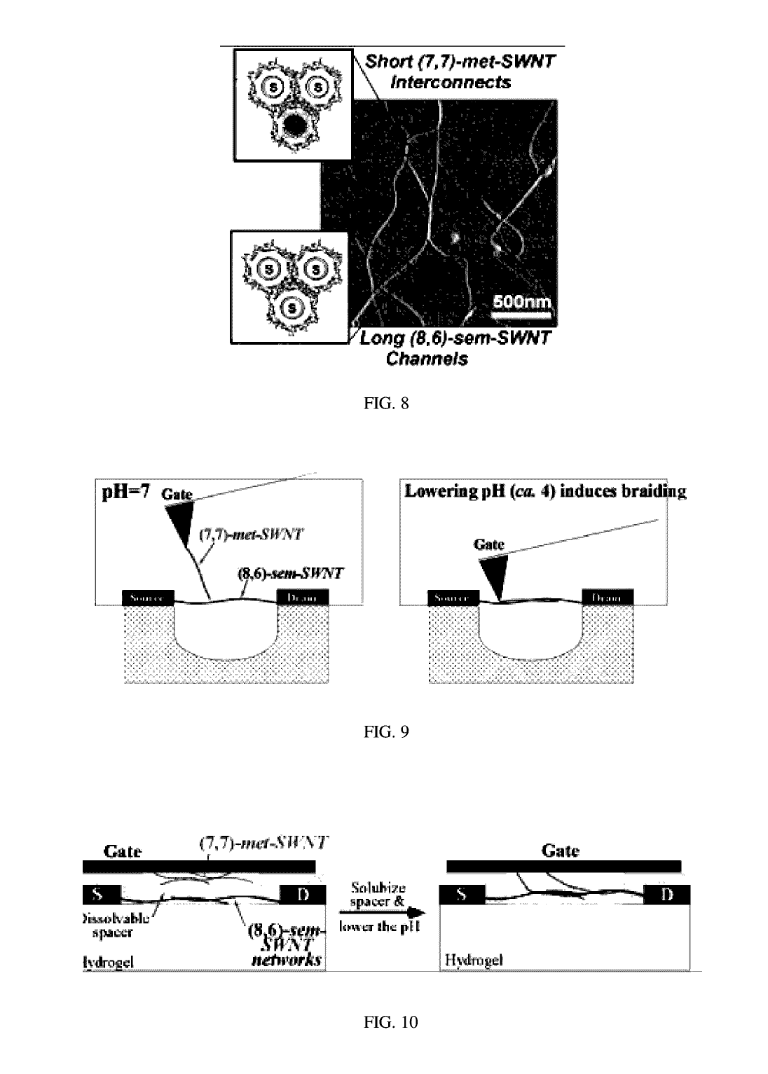

When nanotubes are used in a field effect transistors (FET), the nanotube can be disposed in a network (mat) configuration with a plurality of nanotubes randomly oriented and overlapping between a source and drain electrode. In this configuration, carrier transport is bottlenecked by point intersections of overlapping nanotubes, thus slowing the operation of the FET. The nanocomposites herein can be used to form a robust FET that overcomes this limitation of conventional nanotube-based FETs. FIG. 8 shows a micrograph of an arrangement of sem- and met-SWNTs in a transistor. Such an arrangement can improve connectivity between nanotubes in a macroscopic transistor comprised of a mat-type dispersed nanotubes, which can be, e.g., mostly semiconducting nanotubes. Here, an alignment of the semiconducting nanotubes with incorporation of a short metallic nanotube can improve electrical connectivity and current flow through junctions, e.g., an “X” junction. It is contemplated that the FMN coating can be removed from some of the SWNTs. Further, such an arrangement can be used in a floating gate transistor configuration, where the FMN-wrapped metallic SWNT is a floating gate. As shown in FIG. 8, braided nanocomposites 800 herein can be disposed in a FET structure to facilitate carrier transport along braided sections 801 of the braided nanocomposite 800. Here, superhelix nanocomposites 802, 803 are combined such that short lengths of met-SWNTs 804 are disposed along longer sem-SWNTs 805. Long lengths of superhelix nanocomposite 803 containing only sem-SWNTs 805 form channels of the FET. In this configuration, the met-SWNTs 804 do not short the FET because they do not directly contact a source or drain electrode even though the superhelix nanocomposites 803 that contain only sem-SWNTs 805 can be in direct contact with the source and drain electrodes. Moreover, the nanocomposite FET (referred to herein as a nanotransistor) has enhanced photo response and amplification when irradiated with a quenching wavelength, which will improve transport through the flavin helix 806 disposed on the met-SWNTs 804 and sem-SWNTs 805 of the superhelix nanocomposites 802, 803.

With reference to FIGS. 9 and 10, in an embodiment, a nanotransistor 900 includes a source electrode 901, a drain electrode 902 opposingly disposed to the source electrode 901, and a gate electrode 903 disposed proximate to the source electrode 901 and drain electrode 902. The gate electrode 903 comprising a braided nanocomposite 904, which includes a plurality of superhelix nanocomposites 905, 906. The plurality of superhelix nanocomposites 905, 906 includes a first superhelix nanocomposite 905 in which the (n,m)-SWNT is an (n,m)-sem-SWNT, and a second superhelix nanocomposite 906 in which the (n,m)-SWNT is an (n,m)-met-SWNT. The plurality of superhelix nanocomposites 905, 906 is arranged such that the first superhelix nanocomposite 905 and second superhelix nanocomposite 906 are spaced apart by a separation 907 such that the braided helical configuration is absent in the braided nanocomposite 904. Here, the first superhelix nanocomposite 905 directly contacts the source electrode 901 and drain electrode 902 to interconnect the source electrode 901 and drain electrode 902; and the second superhelix nanocomposite 906 is detached from the source electrode 901, drain electrode 902, or a combination thereof. The separation 907 is removed in response to a change in a condition such that the first superhelix nanocomposite 905 and second superhelix nanocomposite 906 reversibly combine to form the braided helical configuration of the braided nanocomposite 904. The condition can include temperature, pH, application of a voltage, application of current, irradiation with electromagnetic radiation, or a combination thereof.

In an embodiment, as in FIG. 9, the condition is pH, where at a first pH, e.g., a neutral pH, the first and second superhelix nanocomposites 905, 906 are spaced apart. At a second pH, e.g., an acidic pH, the first and second superhelix nanocomposites 905, 906 reversibly combine to form the braided helical configuration of the braided nanocomposite 904 allowing a channel to form between the source 901 and drain 902 electrodes.

In an embodiment, the separation between the first and second superhelix nanocomposites 905, 906 is a removable partition 908, and the condition is removal of the removable partition 908. The removable partition 908 can be, e.g., a compound such as polymer, salt, and the like that is dissolvable by a solvent. Also, the removable partition 908 can be photoactive such that irradiation at a wavelength can remove the removable partition 908.

The nanotransistor 900 is configured to operate in the presence of a liquid 909 disposed on the source electrode 901, gate electrode 903, drain electrode 902, or a combination thereof as in FIG. 9. Similarly, the nanotransistor 900 can operate completely in a solid state as shown in FIG. 10. Such a nanotransistor can operate over a wide frequency range, e.g., from nearly continuous operation up to ultrahigh frequencies such as 100 gigahertz (GHz), specifically up to 30 GHz, and more specifically up to 5 GHz. It is contemplated that the nanotransistor 900 can be biased from low to high potentials, such as kilovolts (kV).

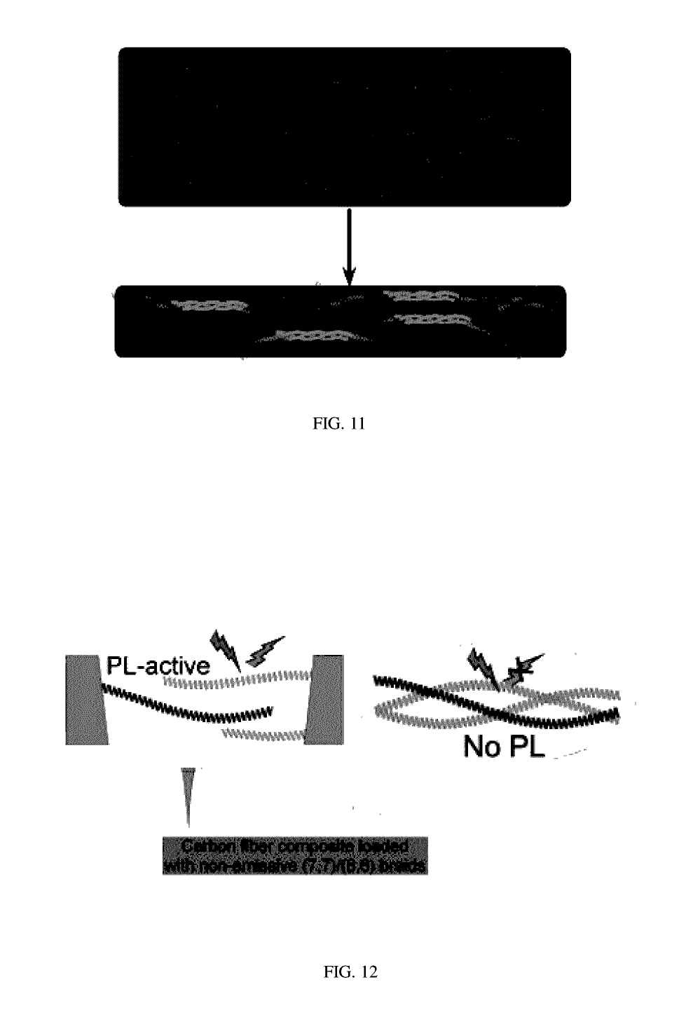

Another use of the nanocomposites herein derives from the reversibility of braiding and de-braiding exhibited by superhelix nanocomposites (e.g., FMN-wrapped SWNTs) that can be exploited in, e.g., a nanomechanical environment such as a nanoactuator. With reference to FIG. 11, an actuator 1100 has superhelix nanocomposites 1101, e.g., FMN-wrapped SWNTs, dilutely dispersed in a medium 1102, e.g., a hydrogel in a non-actuated shape 1103. Exposure of the superhelix nanocomposites 1101 to a decreasing pH in the medium 1102 induces braiding to form the braided nanocomposite 1105 and a corresponding shape change of the medium 1102 to, e.g., an actuated shape 1104. The shape change is reversible. That is, the non-actuated shape 1103 can be recovered by increasing the pH of the medium 1102 to effect de-braiding of the FMN-wrapped SWNTs 1101. Actuation can be imparted by various stimulants that induce braiding and de-braiding of the superhelix nanocomposites 1101.

Thus, in an embodiment, a nanoactuator 1100 includes a medium 1102 and the braided nanocomposite 1105 disposed in the medium 1102. The nanoactuator 1100 is configured to be actuated between a non-actuated state 1107 (non-actuate shape 1103) and an actuated state 1108 (actuated shape 1104) in response to a change in a condition. In the non-actuated state 1107 the plurality of superhelix nanocomposites 1101 are spaced apart by a separation such that the braided helical configuration 1106 is absent among the superhelix nanocomposites 1101. In the actuated state 1108, the separation is removed in response to the change in condition such that the plurality of superhelix nanocomposites 1101 reversibly combines to form the braided helical configuration 1106. Exemplary conditions include temperature, pH, voltage, electrical current, a chemical stimulus, mechanical force, irradiation with electromagnetic radiation, or a combination thereof.

It is believed that the electrical capacitance of the actuator 1100 is changed between the actuated shape 1104 and the non-actuated shape 1103. As a consequence, electrical pulses can be generated by the actuator 1100 in response to loading and unloading, i.e., transitioning between the actuated shape 1104 and the non-actuated shape 1103.

The nanocomposites also can be used as a structural nanoprobe. As shown in FIG. 12, in a structural nanoprobe 1200, the disposition in a medium 1201 (e.g., a composite material) of braided nanocomposites 1202 that include superhelix nanocomposites 1203, 1204 (including sem-SWNTs (in 1203) and sem-SWNTs (in 1204)) can provide a luminescent probe for identification of mechanical fatigue within the medium 1201. Formation of a crack 1205 pulls the superhelix nanocomposites 1202, 1203 apart such that photoluminescent emission 1206 can be recovered from the superhelix nanocomposites 1203 that contain sem-SWNTs. Effectively, the recovered photoluminescent emission 1206 illuminates the crack 1205 by infrared emission and therefore allows visualization of material fatigue or failure at greater depths due to decreased interference from scattering as compared to other assessment methods.

As such, a structural nanoprobe includes a medium 1201 and the braided nanocomposite 1202 disposed in the medium 1201. The plurality of superhelix nanocomposites 1203, 1204 in the braided nanocomposite 1202 includes a first superhelix nanocomposite 1203 in which the (n,m)-SWNT is an (n,m)-sem-SWNT, and a second superhelix nanocomposite 1204 in which the (n,m)-SWNT is an (n,m)-met-SWNT. Accordingly, the braided nanocomposite 1202 has a Fano effect such that the (n,m)-sem-SWNT emits photoluminescent emission 1206 in response to irradiation with primary radiation comprising an excitation wavelength 1207; the photoluminescent emission 1206 from the (n,m)-sem-SWNT is quenched by the (n,m)-met-SWNT in response to irradiation with secondary radiation comprising the excitation wavelength 1207 and a quenching wavelength 1208 when the first 1203 and second 1204 superhelix nanocomposites have the braided helical configuration, and the photoluminescent emission 1206 from the (n,m)-sem-SWNT is emitted in response to irradiation with the secondary radiation when the first 1203 and second 1204 superhelix nanocomposites are spaced apart by a separation such that the braided helical configuration is absent in the braided nanocomposite. The first 1203 and second 1204 superhelix nanocomposites can be spaced apart by a separation in response to the medium 1201 being subjected to mechanical fatigue, failure, stress, slip, cracking, expansion, or a combination thereof.

The nanocomposites methods are further illustrated by the following examples, which are non-limiting.

### EXAMPLES

### Materials and Instrumentation

Flavin mononucleotide (FMN) and sodium dodecyl benzene sulfonate (SDBS) were obtained from Sigma-Aldrich. Deuterated water (D₂O) was obtained from Acros Organics and used as-received. Millipore quality deionized water with resistivity greater than 18 megaohms (MΩ) was utilized for atomic force microscopy (AFM) sample preparation. Single wall carbon nanotubes (SWNTs) synthesized by a high-pressure carbon monoxide process (HiPco) were obtained from Unidym Inc. (Lot# P0341, SWNT diameter (dₜ) distribution 1±0.35 nm).

Dispersions of Flavin Moieties on SWNTs. A mixture of 1 milligram (mg) of HiPco SWNTs and 20 mg of flavin mononucleotide (FMN) were combined in 2 milliliters (mL) of D₂O and dispersed therein by sonication for 4 hours using a cup-horn sonicator (Cole Palmer, Model CP750) at 40% amplitude. The resulting dispersion had a dark green color, which was subjected to centrifugation at 30,000 g (i.e., 30 kg, g being earth's gravitational constant) for 2 hours. Following centrifugation, the supernatant (upper 90 volume percent (vol %), based on the total volume of a sample in the centrifuge tube) was decanted to leave a pellet of large nanotube bundles at the bottom of the centrifuge tube, which were discarded. Prolonged exposure of FMN-dispersed solutions to light was prevented.

FMN-to-SDBS Surfactant Exchange Titration Studies. Surfactant exchange of an FMN helix disposed on SWNTs with a surfactant was investigated. Microliter aliquots of a sodium dodecylbenzenesulfonate (SDBS)/D₂O stock solution (50 millimolar (mM)) were titrated into a sample of 3 ml of FMN/SWNT dispersions. After each SDBS addition, the E^{S}₂₂ transition of SDBS-coated (8,6)-SWNTs was excited at 712 nm and photoluminescent emission (PLE) at 1180 nm was acquired. Titration was stopped when additional SDBS added to the sample no longer increased the PLE intensity at 1180 nm. The 1180 nm PLE intensity versus SDBS concentration data was analyzed using sigmoidal functions based on a Zimm-Bragg formalism to parameterize the titration curve.

Optical Spectroscopy. Photoluminescence spectroscopy measurements were conducted on a Jobin-Yvon Spex Fluorolog 3-211 spectrofluorometer equipped with a photomultiplier tube (PMT) near-infrared (NIR) detector with a 3 nm step size in both excitation and emission wavelength. Excitation and emission light intensities were corrected against instrumental variations using Spex Fluorolog sensitivity correction factors. UV-Vis-NIR absorption measurements were acquired on a Perkin-Elmer Lambda 900 UV-Vis-NIR spectrometer. Raman spectroscopy was conducted using a Renishaw Ramanscope in a backscattering configuration.

Atomic Force Microscopy Imaging. Atomic force microscopy (AFM) characterization was conducted on an Asylum Research MFP-3D using silicon (Si) AFM probes (Asylum Research, Model No. AC 240) with a spring constant 2 N/m, resonant frequency of 70 kHz, and tip radius of about 7 nm. The AFM was operated at an AC tapping mode with a resolution of 512 lines/scan. Samples were prepared by drop-casting and drying the nanocomposite/D₂O dispersion on a freshly cleaved mica slide. The dried samples were washed with multiple cycles of water, which were wicked-off of the mica slide using an absorbent tissue. AFM data (height, amplitude, and phase images) were collected and processed.

For liquid AFM studies, a negatively charged muscovite mica slide was pretreated by immersion in 10% 3-aminopropyltriethoxysilane (APTES) in ethanol at room temperature for 30 minutes. The mica slides were washed with ethanol and deionized water and dried. The FMN/SWNT dispersion was then drop-casted, and incubated to allow adsorption onto the surface of the mica slide for 15 to 20 minutes, without being allowed to dry. The remainder of the dispersion was wicked off without drying, and the mica slide was washed of extra FMN before AFM imaging in deionized water. Height, amplitude, and phase images were collected and processed.

Transmission Electron Microscopy. Transmission electron microscopy (TEM) measurements were performed using an FEI Tecnai T12 Spirit electron microscope operating at 120 kV. High resolution TEM (HRTEM) measurements were carried out using a JEOL JEM-2010 electron microscope operating at 200 kV. The TEM grids had an ultrathin carbon support film on a porous carbon support (Ted Pella, 01824) and were exposed to high-intensity UV light to make them hydrophilic before sample deposition. After centrifuging at 15,000 g, the FMN helix-coated SWNT sample was diluted 100 times, and 5 microliters (μL) was drop-casted onto the TEM grid. Excess sample was wicked off the grid by filter paper after 2 minutes of incubation. After washing with deionized water, 3 μL of uranyl acetate solution (1 wt %) was added to the sample and allowed to incubate for 1 minute before removal by the filter paper.

### Example 1

### Selective Enrichment of FMN/SWNT Species

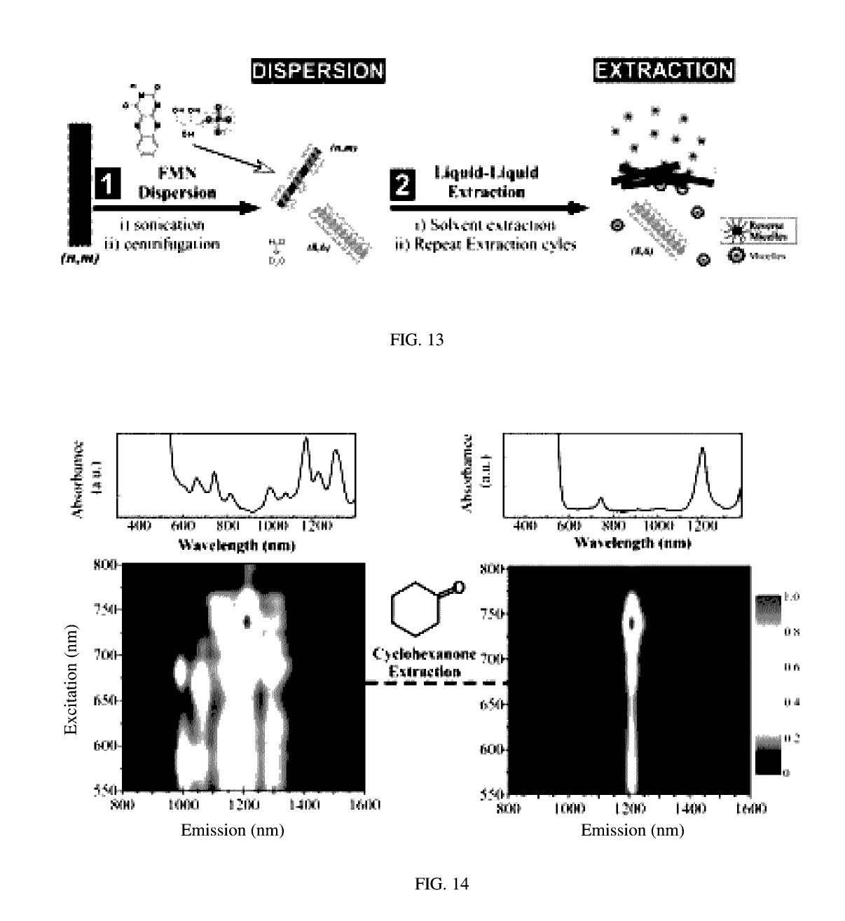

Liquid-liquid extraction was used to select and purify various chirality SWNTs from a large (n,m)-distribution SWNT sample. This extraction methodology is scalable and affords facile extraction of (8,6)- and (7,7)-SWNTs from HiPco-prepared SWNTs. As shown in FIG. 13, HiPco prepared-SWNTs 1300 which (contained about 50 different (n,m)-SWNTs) and FMN 1301 were disposed in water 1302 and subjected to sonication to disperse the HiPco SWNTs 1300 and to form an FMN helix 1303 around the SWNTs 1300, referred to as a nanocomposite 1304 or also as FMN/SWNTs 1304. The dispersion was then centrifuged at 100 kg. While sonication assists in the dispersion of nanotubes, centrifugation ensures that large bundles of SWNTs are removed. Although centrifugation can improve the extent of purity in the final product of FMN/SWNTs 1304, such centrifugation can be bypassed without compromising purity, particularly for dilute samples of SWNTs.

Following collection of the supernatant, the aqueous dispersion of FMN/SWNTs 1304 was introduced into a separatory funnel 1305 to which cyclohexanone 1306 was added to obtain a 3:1 mixture of water to cyclohexanone by volume. The separatory funnel 1305 was shaken and then left undisturbed while an interface 1307 formed between the cyclohexanone phase 1309 (also referred to as oil phase) and aqueous phase 1308. During shaking, the cyclohexanone 1306 contacted the FMN/SWNTs 1304 and either strengthened or disrupted the FMN helix 1303 around the SWNTs 1300. SWNTs 1300 that retained (or strengthened) their FMN helix 1303 were maintained as a dispersion in the water phase 1308, while SWNTs 1300 with disrupted FMN helices 1303 formed a precipitate 1310 at the cyclohexanone/water interface 1307. This process was repeated several times until the desired purity level was reached. The FMN/SWNTs collected from the aqueous phase 1308 after extraction had a purity of 95% purity for (8,6)-SWNTs. The enrichment in (8,6)- and (7,7)-SWNTs in the FMN/SWNTs relative to the HiPco SWNT sample was 9.9%.

The efficiency of this enrichment is strongly dependent on the solvent (e.g., cyclohexanone) selected to form the oil phase for the liquid-liquid extraction. A number of small molecular weight organic solvents (e.g., ethyl acetate, cyclohexanone, and the like) perform well for liquid-liquid extraction). In particular, cyclohexanone efficiently and selectively precipitated all SWNTs from the HiPco sample but (8,6)- and (7,7)-SWNTs as determined by photoluminescence spectroscopy, UV-Vis-NIR absorbance, and Raman characterization. All other SWNTs (i.e., those that are not (8,6)- or (7,7)-SWNTs) have weaker FMN helix-SWNT interactions (such as charge exchange) and lose their FMN helix to some extent which causes aggregation and precipitation at the cyclohexanone/water interface 1307. These precipitated nanotubes can be readily collected and subsequently reused. Therefore, the extraction method herein incurs no loss of SWNTs and offers 100% recyclability thereof.

FIG. 14 shows optical absorption spectra (top panels) and photoluminescent emission maps (lower panels) for FMN-wrapped SWNTs before (left panels) and after (right panels) four extraction cycles using cyclohexanone and water. Emission from (8,6)-SWNTs as well as other SWNTs is shown in the pre-extraction spectra (left panes). However, the post-extraction spectra (right panels) shows that (8,6)-SWNTs are enriched during extraction with removal of other SWNTs due to precipitation from the aqueous phase. It is noted that achiral, metallic SWNTs such (7,7)-SWNTs do not emit photoluminescent emission. In the absorption spectra (top panels), the strong absorbance feature below 550 nm is largely due to FMN in the helix around the SWNTs.

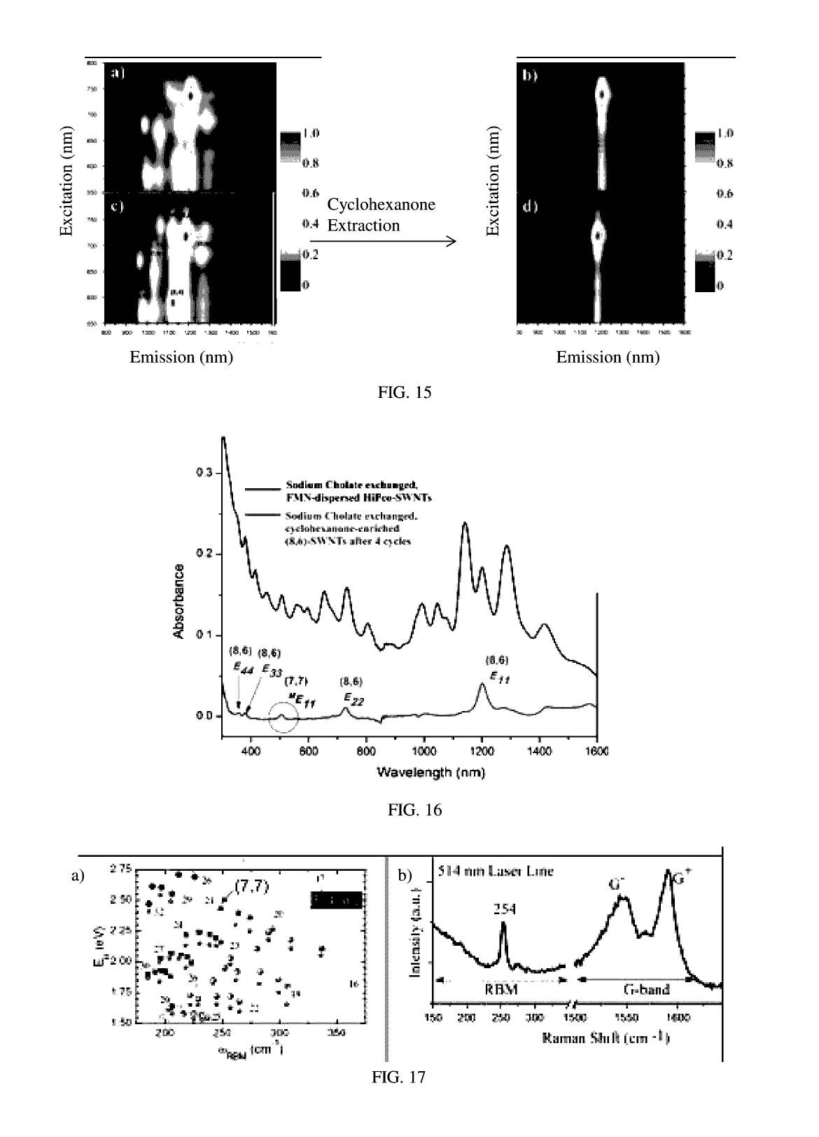

While enriched (8,6)-sem-SWNTs is readily seen in FIG. 14, the strong absorbance of FMN below 550 nm masks the absorbance of the enriched (7,7)-met-SWNT. To obtain spectroscopic information for the (7,7)-met-SWNT, FMN in the FMN helix disposed around the enriched SWNTs was exchanged with a surfactant. For the surfactant exchange, a dialysis technique replaces the FMN with sodium cholate (SC), which is optically transparent around 550 nm. A comprehensive characterization of the SC-exchanged sample is shown in FIGS. 15, 16, and 17, where the photoluminescence emission (PLE) map, UV-Vis-NIR absorbance, and resonance Raman spectroscopy respectively reveal the optical signature of the (7,7)-SWNT along with the characteristic PLE blue-shift for (8,6)-SWNTs, which signifies FMN replacement by SC in FMN/SWNTs.

FIG. 15 shows the PLE map of FMN/SWNTs before (FIG. 15 (a)) and after (FIG. 15(b)) oil-water extraction with cyclohexanone. The photoluminescent emission distribution post-extraction (FIG. 15(b)) was remarkably smaller than before extraction (FIG. 15(a)). The highest intensity peak corresponded to the (8,6)-SWNTs in the FMN/SWNTs. FIG. 15 also shows PLE maps before (FIG. 15(c)) and after (FIG. 15(d)) oil-water extraction (again with cyclohexanone) for nanocomposites produced by replacing the FMN helix surrounding SWNTs with sodium cholate (SC). Surfactant exchange with SC verifies that the selected enrichment does not arise from different degrees of charge transfer quenching in the photoluminescence of the SWNTs but rather exclusion of all but (8,6)-SWNTs in enriched FMN/SWNTs. For example, the PLE of (8,4)- and (6,5)-SWNTs (both sem-SWNTs) is typically attenuated in the presence of FMN. Upon cyclohexanone extraction, these species clearly were absent.

While PLE allows determination of the distribution of sem-SWNTs in nanocomposites, met-SWNTs that have no band gap and therefore do not emit PLE. To obtain spectroscopic information for nanocomposites of met-SWNTs, UV-Vis-NIR absorption data were obtained and are shown in FIG. 16. The upper spectrum corresponds to SC-exchanged samples before cyclohexanone extraction to enrich the sample. The lower spectrum corresponds to the SC-exchanged samples after cyclohexanone extraction enriched the sample. That is, the absorption spectra confirmed selective enrichment of (8,6)-SWNTs as evidenced by the distinct van Hove singularities (E^{S}₁₁, E^{S}₂₂, E^{S}₃₃, and E^{S}₄₄). Also present in the absorption spectra is the peak at about 500 nm due to the metallic armchair (7,7)-SWNT.

Assignment of the 500 nm absorption feature to the (7,7)-SWNT was verified by Resonance Raman Spectroscopy (RRS). As shown in FIG. 17(a), a Raman shift correlation chart shows that laser excitation at 514 nm (2.41 eV) is in close resonance with the 500 nm E^{M}₁₁ transition of the (7,7)-SWNT. In the experiment, the sample was excited at 514 nm, and the Raman spectrum was collected (FIG. 17(b)). The radial breathing mode (RBM) of this metallic nanotube species is near resonant at 514 nm and appears as an RBM Raman shift at about 250 cm⁻¹, as shown in FIG. 17(b). The Raman shift correlation chart shows that only the (7,7)-SWNTs from family 21 (i.e., the 2n+m family) is resonant at 514 nm, with a strong peak at 254 cm⁻¹. However, the (8,6)-SWNT belongs to the family 22 (2n+m family) is non-resonant since the 2.41 eV excitation laser (514 nm) was very far from the E^{S}₂₂ transition of the (8,6)-SWNT, which is resonant at about 725 nm (1.71 eV). Consistent with the absorption data of FIG. 16, the presence of both metallic (7,7)-SWNTs and semiconducting (8,6)-SWNTs in this nanocomposite sample is confirmed by their respective G⁻ and G⁺ bands in the Raman spectrum of FIG. 17.

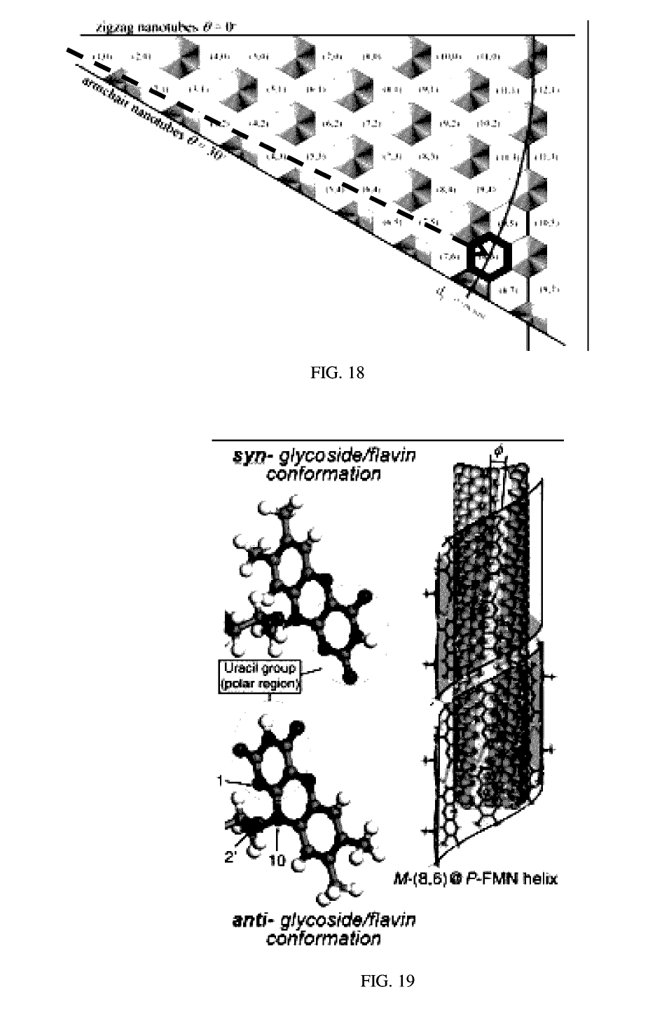

Without being bound by theory, FIG. 18 shows a Weisman plot where SWNT chirality given by (n,m) indices are depicted against their Hamada vector 1800 (Cₕ that defines the nanotube diameter) and chiral angle (θ). The 0.98 nm diameter dₜ of the (7,7)-SWNT is very close to that of the (8,6)-SWNT (0.97 nm). FIG. 19 depicts, for an FMN/SWNT, the atomic configuration of an 8/1 FMN helix in reference to a left-handed M-(8,6)-SWNT. The 8/1 FMN helix is arranged in armchair configuration, which is in a “quasi-epitaxy” lattice registry with the underlying (8,6)-SWNT graphene lattice with a small misalignment (φ) shown in FIG. 19 The misalignment progressively decreases as the chiral angle (θ) deviates more from 30°. Therefore, the FMN/cyclohexanone enrichment of specific SWNT species originates from quasi-epitaxy lattice registry of the 8/1 FMN helix with the underlying graphene lattice of the SWNT. Moreover, by controlling an orientation the of the phenyl rings of the surrounding flavin helix, “quasi-epitaxial” selection of the corresponding SWNT was achieved for FMN. This can be extended to other flavin helix-SWNT nanocomposites.

Due to SWNT enrichment via quasi-epitaxy, a preferential selection of one handedness of (8,6)-SWNT was achieved. As shown in FIG. 19, to facilitate a better lateral packing of adjacent FMN moieties, the 10 position (N(10)) of the isoalloxazine ring adopts an sp³ hybridization. Such hybridization results in two different conformations for the N(10)-attached d-ribityl chain, directing this chiral moiety in either sides of the isoalloxazine ring. FIG. 19 also shows the two energy-minimized conformations of the FMN (R-FMN), where the d-ribityl phosphate side chain resides in either sides of the isoalloxazine ring. This brings the 2′ hydroxyl group closer (FIG. 19, top structure) or farther (FIG. 19, bottom structure) from the circled polar uracil group of the isoalloxazine ring structure. Molecular simulations indicated that the anti-like conformation is slightly more stable than the syn-like conformation of FMN. Also, the anti-like conformation of FMN prefers to organize in right-handed helices, as shown in FIG. 19.

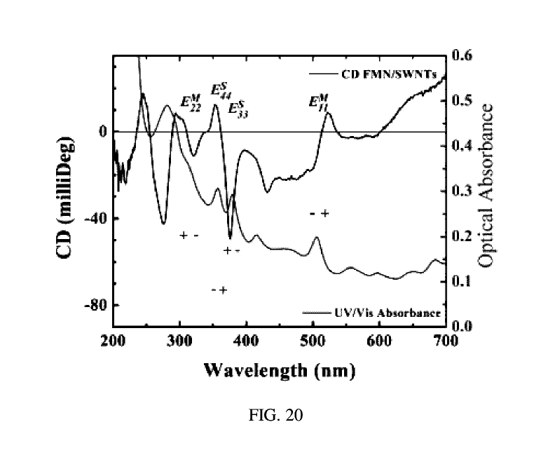

Treatment of the FMN/SWNT with cyclohexanone substantially increased the FMN order in the helix around the enriched SWNTs so that surfactant exchange with, e.g., sodium cholate (SC) was difficult to achieve at 100% displacement of the FMN unless the exchange was performed above the temperature at which the ordered FMN monolayer dissociates from the underlying SWNT. In the FMN/SWNTs a monolayer of FMN is disposed on the two enriched SWNT chiralities. The presence of the FMN monolayer was verified by differential subtraction of UV-Vis-NIR spectra following sequential SC replacement in conjunction with the blue shift observed from SC-dispersed SWNTs (data not shown). FIG. 20 shows circular dichroism (left y-axis) and optical absorption (right y-axis) versus wavelength for enriched sample produced via cyclohexanone treatment where excess of FMN has been replaced by sodium cholate (SC), leaving a monolayer of highly ordered FMN around the two enriched nanotube-chiralities. Since the enriched (7,7)-SWNT is achiral, optical activity observed at 505 nm due to the E^{M}₁₁ transition arose from induced circular dichroism (ICD) of the chiral FMN helix to the (7,7)-SWNT. The chiral FMN helix couples its chiral dipole moment to the underlying achiral nanotube and induces handedness in the electronic transition of the achiral species, i.e., absorption at 312 nm of the E^{M}₂₂ transition and at 505 nm of the E^{M}₁₁ transition of the enriched (7,7)-SWNT. Analysis of the +/−pattern for the E^{M}₂₂ and E^{M}₁₁ electronic transitions showed that the handedness of the FMN helix was positive (i.e., P or anti), which was consistent with calculations on this system. Further analysis of the circular dichroism data allowed determination of the handedness of the chiral (8,6)-sem-SWNT of the enriched FMN/SWNT. Analysis of the +/−patterns for the well-resolved E^{S}₃₃ (at 379 nm) and E^{S}₄₄ (at 354 nm) transitions of the (8,6)-SWNT showed that the selectively enriched SWNT in the FMN/SWNT had an opposite handedness with that of the FMN helix. Therefore, the overall structure of the enriched FMN/SWNT is that of a P-FMN helix wrapped around an M-(8,6)-SWNT (or (6,8)-SWNT.

The simplicity of this method to enrich a given handedness of sem-SWNT is due to the chiral helix that FMN forms on SWNTs. This contrast with many surfactants that are nonchiral and do not afford such concurrent chirality and handedness selection.

### Example 2

### Formation of Highly Ordered Flavin Helices Around SWNTs

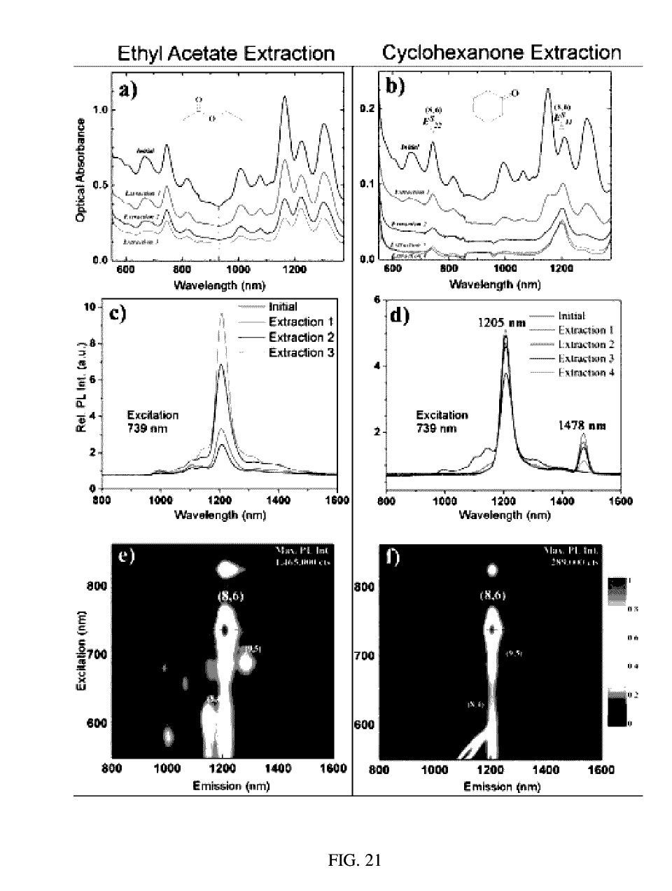

The unique ability of cyclohexanone based oil-water extraction to highly enrich particular SWNT species having a flavin helix is believed to depend on modulation of the strength of FMN helices around the SWNTs. Weak FMN/SWNT complexes were disrupted and precipitated at the oil-water interface. The bonds between strongly complexed FMN/SWNT nanocomposites were strengthened so that the FMN/SWNT had an enrichment in chirality and handedness. In addition to cyclohexanone, other organic solvents used in the extraction were found to improve the quality of the flavin helix. FIG. 21 shows results for optical absorption and PLE experiments for ethyl acetate-water extraction as compared with similar results for cyclohexanone-water extraction to form enriched FMN/SWNT nanocomposites using methods similar to those used in Example for sample preparation and extraction.

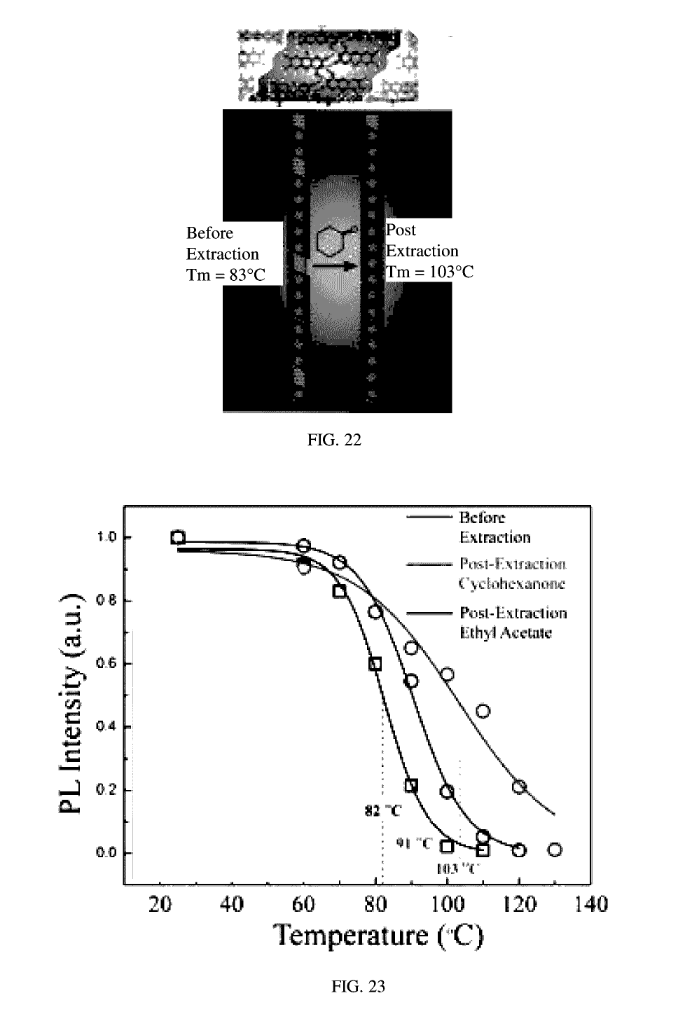

As shown in FIGS. 21(a),(b), background suppression in the absorption spectra indicated that cyclohexanone disrupted the weak FMN/SWNT helices more than ethyl acetate. Disruption of the weakly bound complexes caused them to rapidly precipitate at the oil/water interface. For FMN/SWNT nanocomposites that survived the harsh plasticization treatment of the organic solvent, the resulting FMN helix was improved through solvent-based annealing of the helix on the surface of the selected SWNT. This effect can be seen in FIGS. 21(c),(d) where repeated extraction cycles improve the photoluminescent (PL) intensity. The quantum efficiency (PL_{rel.}/UV_{rel.}) is a good indication of the degree to which SWNTs are surrounded by the FMN helix. For a highly ordered FMN helix that covers a substantial amount of the SWNT surface, the wall of the SWNT is unexposed and therefore inaccessible to external dopants or oxidative species that could be deleterious to their photoluminescent, electrical, mechanical, or chemical properties. The effect of solvent annealing during extraction is schematically illustrated in FIG. 22.

To verify that the order of post-extraction FMN helix has been improved, the order-to-disorder temperature for pre- and post-extraction samples were assessed using photoluminescent emission from the FMN/(8,6)-SWNT nanocomposite as an internal PL probe. Here, by increasing the temperature of the suspension containing the FMN/SWNTs, the FMN helix begins to dissociate and cause nanotubes to aggregate, which significantly quenches their photoluminescent emission. FIG. 23 shows the temperature-dependent photoluminescent (PL) emission before and after for cyclohexanone extraction as well as for ethyl acetate extraction. The post-extraction FMN helix had a higher dissociation transition than the pre-extraction helix=82° C.) for cyclohexanone (Tm=103° C.) and ethyl acetate (Tm=91° C.) treated samples.

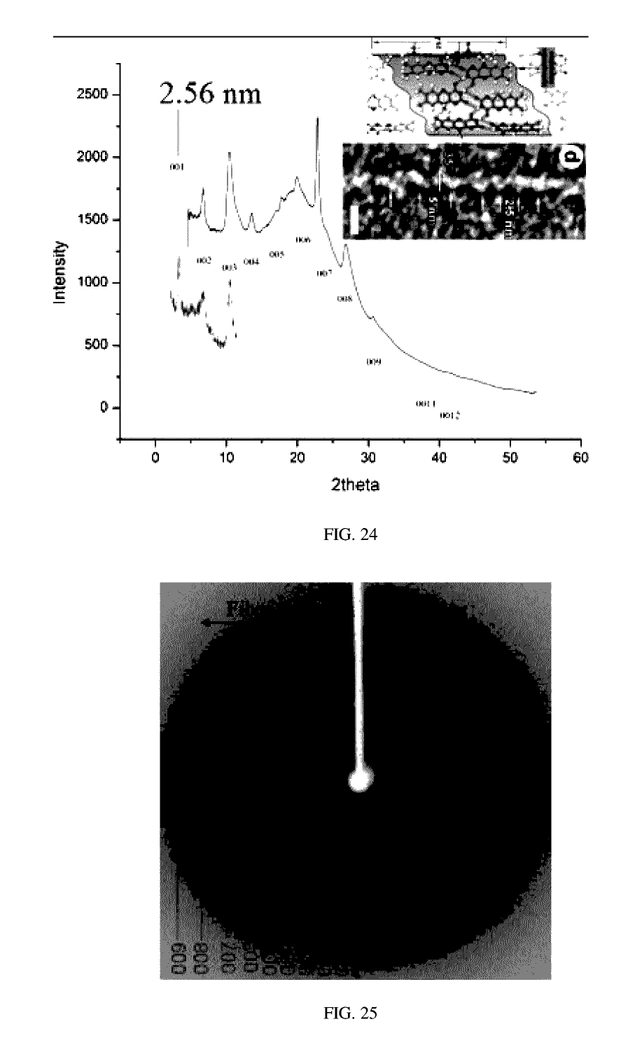

The distinct sigmoidal transition observed in the PL emission intensity of the specific nanotube helix (i.e., FMN/(8,6)-SWNT) shown in FIG. 23 is analogous to “dissociation” (also referred to as melting) of ds-DNA into two individual single stands of DNA. This distinctive transition is consistent with the presence of a well-defined, ordered structure, which can be thought as “crystalline,” assuming long-range order. In order to ascertain whether FMN/SWNT helical structures possess long-range order, X-ray diffraction was performed on cyclohexanone-extracted, FMN/SWNTs, which were mostly (8,6)- and (7,7)-SWNTs prepared as in Example 1. For X-ray diffraction studies, the enriched samples were slowly dried, wherein they formed fibrous-like structures, and the nanotube orientation became apparent. FIGS. 24 and 25 show both 1D (WAXS and SAXS) and 2D XRD patterns of the enriched FMN/SWNTs. The strong 001 periodicity had a 2.56 nm repeat-pattern and extended for 12 fundamentals, which provided support for the presence of a well-defined, long-range ordered helix of FMN along the longitudinal axis of the SWNTs. This closely matches with the 2.5 nm repeat pattern observed via HRTEM that is shown as an inset in FIG. 24. Moreover, the pronounced 008 peak provided additional evidence of the presence of an 8/1 FMN helix surrounding the enriched (8,6)- and (7,7)-SWNTs. These data revealed that cyclohexanone treatment of FMN/SWNT nanocomposites plasticized the FMN helix and provided adequate mobility to anneal defects (such as the helix defect (gap) shown FIG. 22) so that the helix attained long-range order and well-defined melting.

### Example 3

### Formation of Nanocomposite Superhelix

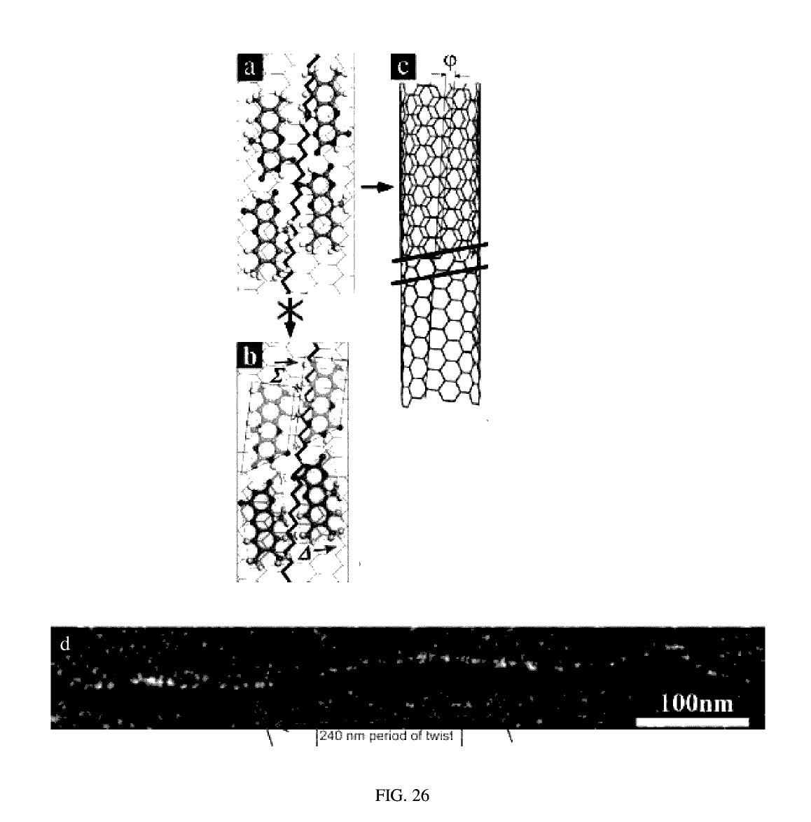

The long-range order of the FMN helix disposed around SWNTs discussed in Example 2, provided additional insight regarding the structure of the enriched nanocomposites of FMN/SWNTs. That is, since the flavin helix exerted a torsional force on the underlying SWNT, and the SWNT relieved the force by forming a twist along the length of the SWNT. Without wishing to be bound by theory, the quasi-epitaxial organization of flavin moieties on the SWNTs produced the twist (also referred to as a writhe). Therefore, FMN overcame the exceptional mechanical properties (strength, modulus, stiffness, and the like) of the SWNTs. This quasi-epitaxy model is illustrated in FIG. 26.

From an energetics perspective, the armchair orientation of the isoalloxazine ring system of the flavin moiety in the helix can improve its π-π interaction with the slightly tilted (8,6)-SWNT graphene lattice (the bold zigzag in FIG. 26(a)), which can occur by either flavin rotation (as in FIG. 26(b)) or by twisting the SWNT at an angle φ as shown in FIG. 26(c) (untwisted shown in black, twisted in red). The untwisted SWNT configuration has a higher energy than the twisted SWNT structure, which is therefore more energetically stable with respect to addition of the FMN helix to the SWNT. The twist in the lattice of the SWNT at the molecular level has one-to-one correlation with the electronic, optical, and mechanical properties of the FMN/SWNT nanocomposites. As a result of minimizing the energy of the FMN/SWNT, the SWNT obtains a twist with a periodicity of about 240 nm as shown by the transmission electron microscope image in FIG. 26(d). Thus, the enriched FMN/SWNT nanocomposites have superhelical configurations.

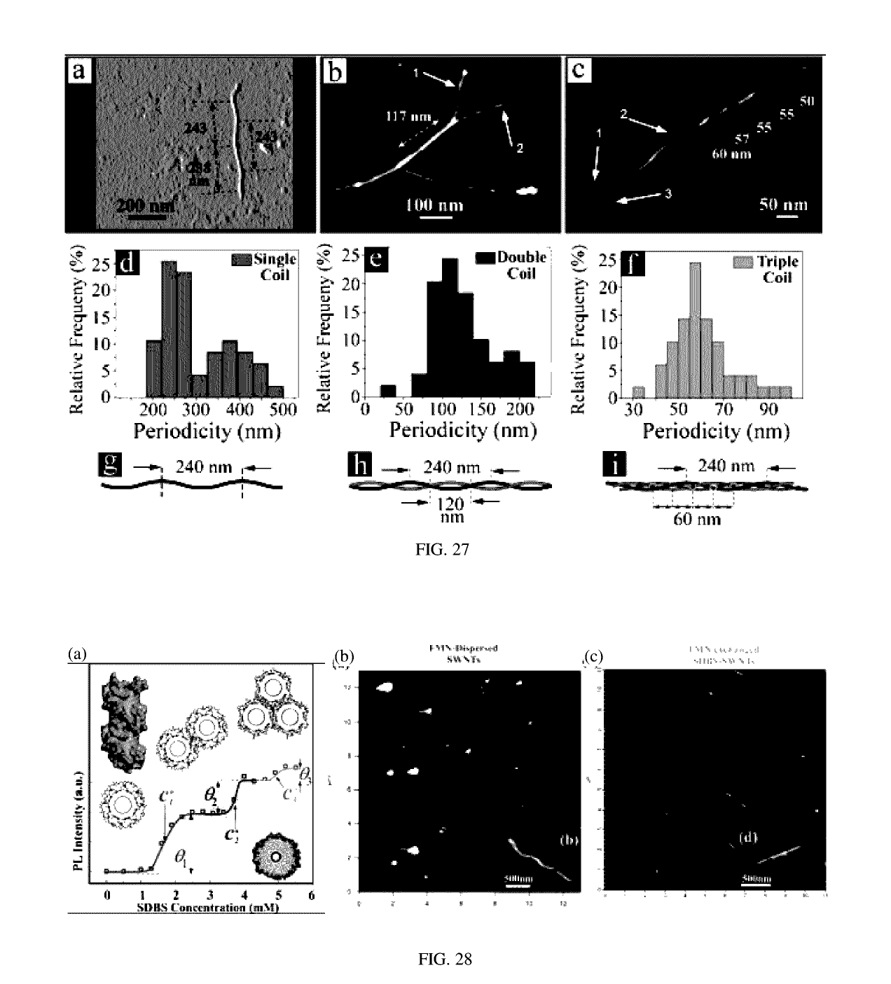

In addition to single FMN/SWNTs in a superhelix nanocomposite, braided nanocomposites of double and triple superhelix nanocomposites were observed. FIG. 27 shows atomic force microscopy (AFM) micrographs of single, double, and triple nanocomposite superhelices of FMN-wrapped SWNTs with corresponding statistical distributions of their periodicity. Advantageously, such braided nanocomposites were highly resilient and never lost their FMN helices.

The braided structures shown in FIG. 27 were corroborated with transitions observed upon surfactant exchange titration, data for which is shown in FIG. 28. Braided nanocomposites of FMN/SWNTs were titrated by sodium dodecylbenzenesulfonate. The presence of supra-molecular braided assemblies was reflected in the titration transitions as the FMN/SWNTs lost FMN from their helices and adopted a micellar configuration of SDBS. FIG. 28(a) shows a triple transition during titration consistent with triple, double, and single superhelix nanocomposites that were titrated by SDBS. FIGS. 28(b) and (c) show the loss of superhelicity upon exchange of the FMN helix with SDBS. FIG. 28(b) shows an AFM micrograph for FMN/SWNT braided nanocomposites (which had a writhe structure shown in the inset) before titration. FIG. 28(c) shows an AFM micrograph for FMN/SWNT braided nanocomposites after titration. Here, the inset shows loss of the FMN helix and the writhe in the SWNT.

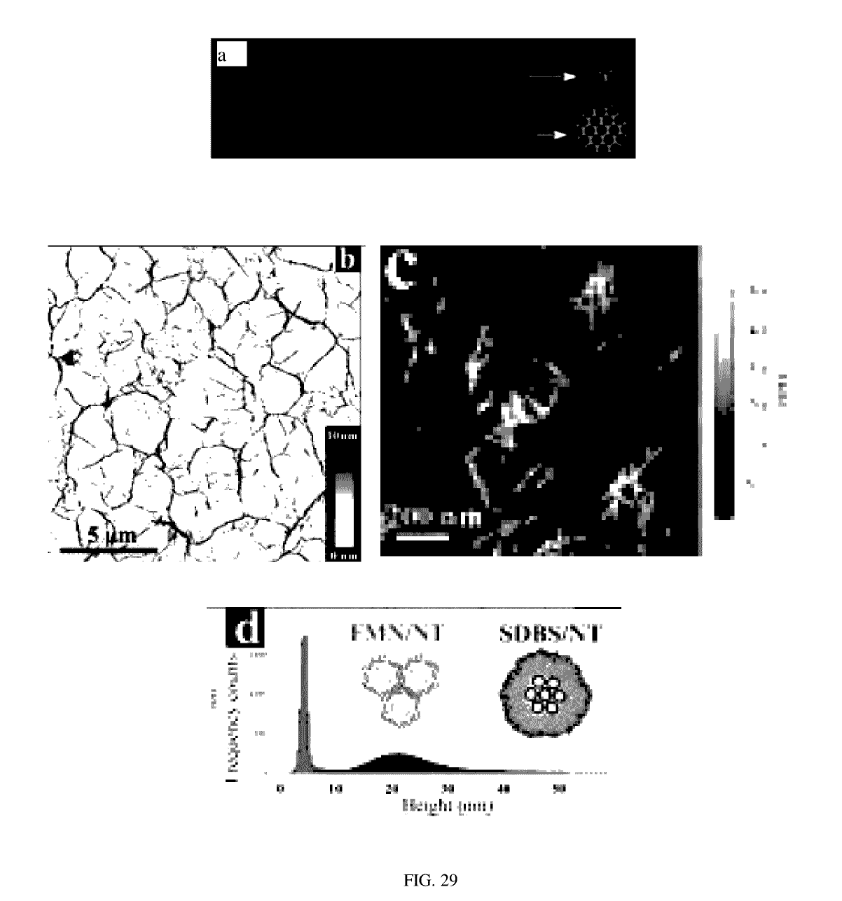

Superhelicity of the FMN/SWNT is incompatible with extended rope-lattice packing. That is, the superhelix FMN/SWNT nanocomposites form braided nanocomposites that have a self-limited number of the superhelix nanocomposites. The self-limited bundling behavior of superhelix FMN/SWNT nanocomposites is depicted in FIG. 29(a), which shows self-limited bundle-growth of writhed superhelix nanocomposites as opposed to linear helices.

FIGS. 29(b) and (c) respectively show AFM micrographs of concentrated (10.7 mg/ml) FMN/SWNTs and SDBS/SWNTs from which the respective height histograms shown in FIG. 29(d) were derived. The height histograms had a narrow distribution for the self-limited size distribution of FMN/SWNT braided nanocomposites (which peaked at a height of 4.7 nm and were mostly triple braids) as compared to the broad height distribution found for the uncontrolled bundling of SDBS/SWNTs (which peaked at a height of 23.7 nm). The significantly narrower distribution in the height histogram of FMN as compared to SDBS indicated that the writhed geometry of FMN/SWNTs frustrated the growth of large bundles and self-limited the number of braided superhelix nanocomposites them to a maximum of triple braids as allowed by the magnitude of the writhe amplitude.

### Example 4

### Nanoplasmonics of Braided Nanocomposites

The braided nanocomposite that includes metallic and semiconducting SWNTs have beneficial properties. Self-assembly of the superhelix nanocomposites into the braided nanocomposite allows reversible control of the formation and dissociation of the braided structures. The size uniformity of the FMN helix and resulting superhelix enables seamless formation of braided nanocomposites between an (8,6)-semiconducting (S) and (7,7)-metallic (M) species without development of epitaxial strain. Further, the distance between the various combinations of the two species (i.e., S-S, S-M, M-M, S-S-M, S-M-M, and the like) can be controlled by lattice interpenetration between the helices of the FMN/SWNT. Hence, changing the substituent of the flavin moiety produces control of this distance at the molecular level at distances from angstroms (Å) to nanometers (nm).

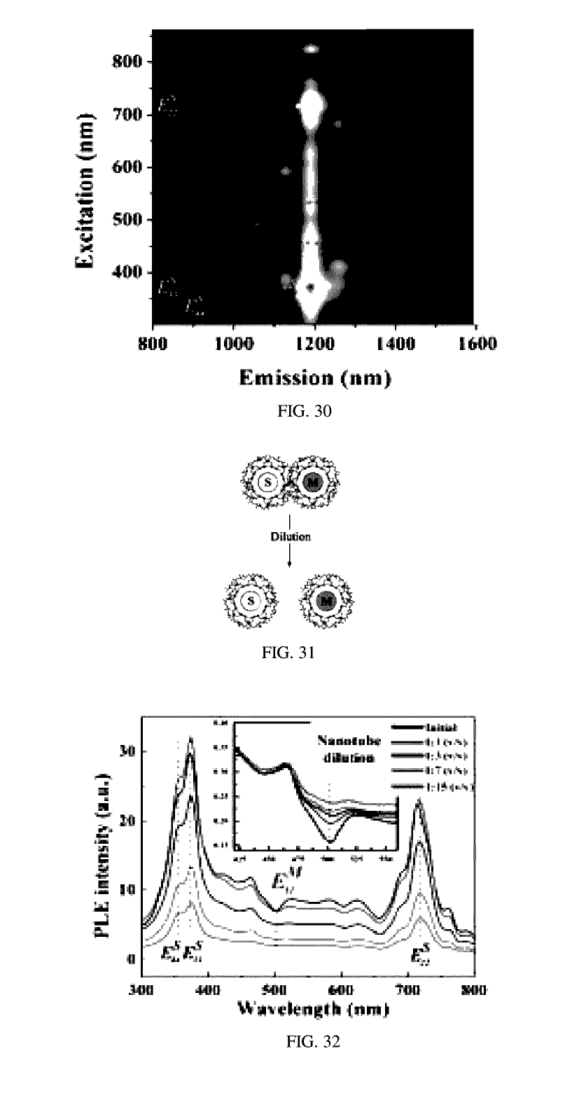

FIG. 30 shows the effect on photoluminescent properties of the braided nanocomposites that contain metallic and semiconducting SWNTs. Here, the presence of the flavin helices around both of the metallic and semiconducting SWNTs prevented the direct contact of the two species and also controlled inter-SWNT tube distance. Direct contact of the sem-SWNT with the met-SWNT would cause photoluminescent emission quenching and considerable line broadening of their respective electronic transitions. Thus, the presence of non-radiative pathways due to mirror-induced charges on the bandgap of the (8,6)-sem-SWNT by the neighboring metallic (7,7)-SWNT species (that causes carrier trapping and PL quenching) was prevented along the metallic continuum except in the wavelength vicinity of the E^{M}₁₁ transition, which peaked at about 500 nm and is encircled in FIG. 30. Thus, photoluminescent emission of the (8,6)-SWNT at about 1200 nm was absent for an excitation wavelength of about 500 nm caused by excitation of the E^{M}₁₁ transition of the adjacent (7,7)-SWNT in the braided nano composite. As shown in FIGS. 31 and 32, upon progressive dilution, the superhelix nanocomposites of the braided nanocomposite dissociate (depicted in FIG. 31), and the individualized FMN/(8,6)-sem-SWNTs recover their photoluminescent emission around an excitation wavelength of 500 nm, an effect known as the Fano effect.

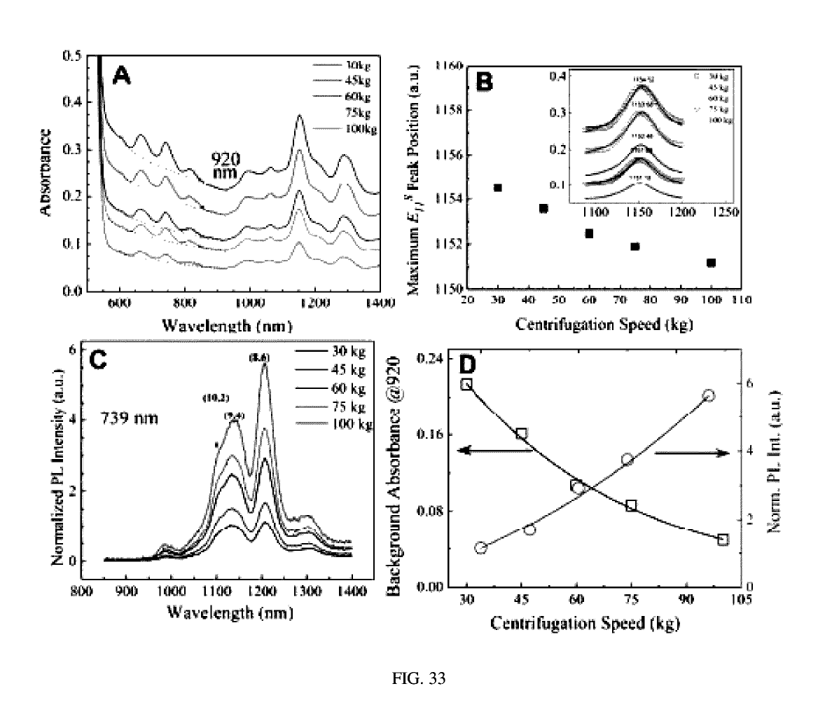

For braided nanocomposites that contain superhelix nanocomposites of only semiconducting SWNTs, absorption properties were studied to discern spectroscopic features for this class of braided nanocomposites. These spectroscopic features are shown in FIG. 33 and are exemplified in terms of the characteristic red-shift that all the Eᵢᵢ transitions undergo upon braiding. FIG. 33 shows the spectroscopic characteristics of FMN/SWNT braided nanocomposites that include only superhelix nanocomposites of (8,6)-SWNTs. In these experiments, the braided nanocomposite sample was subjected to centrifugation and subsequent spectroscopic characterization for five different centrifugation settings (30 kg-100 kg). The Vis-NIR absorbance spectra of FMN-dispersed SWNTs in FIG. 33(a) shows decreasing absorption intensity with increasing centrifugation speed, and the E^{S}₁₁ transition had a 3 nm blue shift with increasing centrifugation speed (FIG. 33(b). However, as shown in FIG. 33(c), the normalized photoluminescent emission intensity from the E^{S}₂₂ transition following excitation at 739 nm increased with increasing centrifugation speeds. FIG. 33(d) shows results for background absorption at 920 nm (left abscissa, obtained from FIG. 33(a)) and absorbance-normalized photoluminescent emission intensity at 1210 nm (right abscissa) of the (8,6)-SWNTs as a function of centrifugation speed. In view of this data, greater centrifugation speeds removed more aggregated species of FMN/SWNTs as manifested by the decreasing absorption background at 920 nm and progressively increasing normalized photoluminescent emission intensity.

As shown by the spectroscopic data, the braided nanocomposites have unique optical properties. Moreover, they possess reversible control of braiding and dissociation of their constituent FMN-wrapped SWNTs. These properties were investigated to determine the effect of pH on the formation and dissociation of FMN/SWNT braided nanocomposites. It was found that individual FMN-wrapped SWNTs were stable over a broad pH range, e.g., from pH of 4 to 10. At less than a pH of 4, phosphate side groups of FMN lost their charge due to neutralization under acidic conditions, which caused excessive braid formation. At a pH of 10 and greater, the FMN helix dissociation due to loss of hydrogen bonding (via N-H ionization of the uracil sub-group of the flavin ring system) resulted in the destruction and removal of the FMN helix from the underlying SWNT and subsequent SWNT bundling with complete loss of photoluminescence.

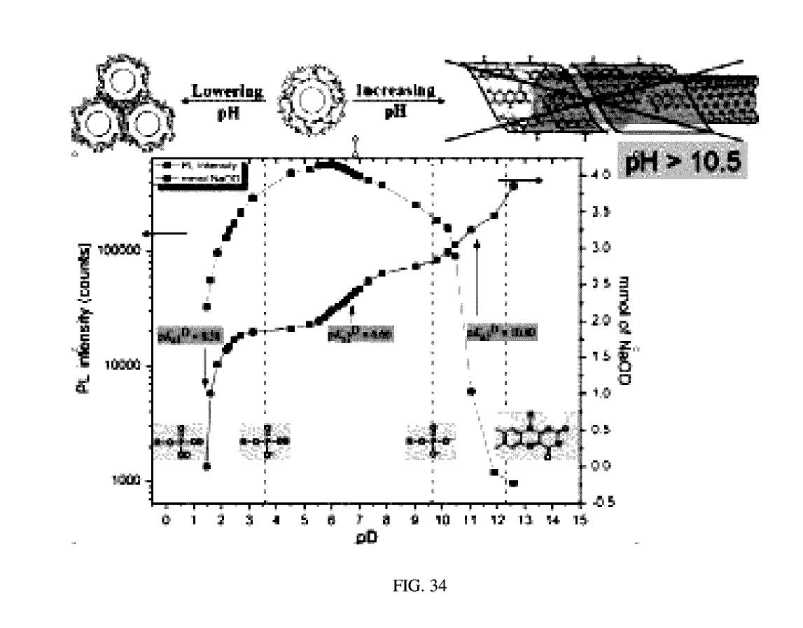

Results of pH testing of the braided nanocomposite are shown in FIG. 34. Here, the photoluminescent intensity is shown versus the pH (labeled as pD in the graph since NaOD was used as titrant). The braided nanocomposite had pH-dependent formation and dissociation of FMN/(8,6)-SWNT braided nanocomposites that appeared as a function of the ionization transitions of several groups in FMN, particularly the phosphate side group and the N-H group of the uracil group in the flavin ring system. As determined from photoluminescent emission of the (8,6)-SWNT, phosphate ionization events occurred around a pH of 2 and 4 and were coupled with SWNT braiding. SWNT braiding was an outcome of the neutralization of the charge on the phosphate side group that reduced ionic repulsion among neighboring nanotubes. As the pH was increased to a level greater than the formation of doubly ionized phosphate side groups and eventually ionization of the uracil sub-group, the FMN helix dissociated and exposed the underlying SWNTs to the solution. At this pH, uncontrolled nanotube aggregation occurred.

From the examples, it can be seen that nanocomposites can be formed with an enrichment of certain SWNTs having a flavin helix thereon. These enriched nanocomposites have structural features that lead to controllable braiding and formation of braided nanocomposites that exhibit unique optical features useful in numerous applications.

The singular forms “a,” “an,” and “the” include plural referents unless the context clearly dictates otherwise. “Or” means “and/or.”

Various numerical ranges are disclosed in this patent application. Because these ranges are continuous, they include every value between the minimum and maximum values. The endpoints of all ranges reciting the same characteristic or component are independently combinable and inclusive of the recited endpoint.

As used herein, “a combination thereof” refers to a combination comprising at least one of the named constituents, components, compounds, or elements.

All references are incorporated herein by reference.

While the invention has been described with reference to various embodiments, it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to any particular embodiment disclosed for carrying out this invention, but that the invention will include all embodiments falling within the scope of the appended claims.

What is claimed is:

1. A method for enriching an initial concentration of (8,6)-SWNTs, (7,7)-SWNTs, or a combination thereof, from a plurality of (n,m)-SWNTs, the method comprising:
dispersing the plurality of (n,m)-SWNTs in a first medium comprising flavin moieties under conditions effective for the flavins to self-assemble in a wrapped pattern around the (n,m)-SWNTs, to form a nanocomposite;
contacting the nanocomposite with a second medium that is immiscible with the first medium under conditions effective to enrich, in the first medium, the concentration of an (8,6)-SWNT nanocomposite, (7,7)-SWNT nanocomposite, or a combination thereof relative to the initial concentration in the plurality of (n,m)-SWNTs; and
separating the first medium from the second medium.

2. The method of claim 1, further comprising removing from the first medium the nanocomposite comprising all other (n,m)-SWNTs but (n,m)-SWNTs selected from the (8,6)-SWNT and (7,7)-SWNT, (n,m)-SWNTs without a flavin moiety disposed thereon, bundled nanotubes, impurities, and combinations comprising at least one of the foregoing.

3. The method of claim 2, wherein separating the first medium and second medium comprises partitioning the first medium from the second medium to form an interface at a boundary between the first medium and second medium.

4. The method of claim 3, wherein removing comprises precipitating, at the interface between the first medium and the second medium the nanocomposite comprising all other (n,m)-SWNTs but (n,m)-SWNTs selected from (8,6)-SWNT and (7,7)-SWNT; (n,m)-SWNTs without a flavin moiety disposed thereon; bundled nanotubes; impurities; and combinations comprising at least one of the foregoing.

5. The method of claim 2, wherein removing comprises a process including liquid-liquid extraction, filtration, fractional filtration, size-exclusion based chromatography, density gradient centrifuging, chromatography, anionic chromatography, silica gel columns, electrophoresis, dielectrophoresis, or a combination thereof.

6. The method of claim 5, where centrifuging is conducted at a centrifugal force of about 2 g to about 500,000 g.

7. The method of claim 1, further comprising collecting the enriched nanocomposite from the first medium after separating the first medium and the second medium.

8. The method of claim 1, wherein separating the first and second medium enriches a first enantiomer of the (8,6)-SWNT in the enriched nanocomposite in an amount greater than a second enantiomer of the (8,6)-SWNT.

9. The method of claim 8, wherein the first enantiomer is M-(8,6)-SWNT.

10. The method of claim 1, wherein the pattern of the flavin moieties disposed on the (n,m)-SWNTs in the enriched nanocomposite is a helix.

11. The method of claim 10, wherein the helix has a plus (P)-handedness.

12. The method of claim 1, wherein the flavin moieties comprise flavin mononucleotide, flavin adenine dinucleotide, FC12 (10-dodecyl-7,8-dimethyl-10H-benzo[g]pteridine-2,4-dione), riboflavin, or a combination thereof.

13. The method of claim 12, wherein the flavin moieties are substituted with substituent.

14. The method of claim 13, where the flavin moieties are substituted at the 7, 8, or 10 positions with a substituent.

15. The method of claim 13, wherein the substituent comprises a complex chiral center; the complex chiral center being a R- or L-ribityl, R- or L-ribityl phosphate, R- and L-ribityl diphosphatic adenine; R- or L-arabityl, R- or L-arabityl phosphate, R- and L-arabityl diphosphatic adenine; R- or L-xylityl, R- or L-xylityl phosphate, R- and L-xylityl diphosphatic adenine; R- or L-xylityl, R- or L-xylityl phosphate, R- and L-xylityl diphosphatic adenine; R- or L-lyxytyl, R- or L-lyxytyl phosphate, or R- and L-lyxytyl diphosphatic adenine.

16. The method of claim 13, wherein the substituent is an oligomer, a homopolymer, a copolymer, a block copolymer, an alternating block copolymer, a random polymer, a random copolymer, a random block copolymer, a graft copolymer, a star block copolymer, a dendrimer, a liquid crystalline polymer, a lyotropic crystalline polymer, a dye, a pigment, a drug, a crystallizable drug, a therapeutic biologically active agent, a pharmaceutic biologically active agent, a protein, a nucleic acid, a fullerene, nanocrystals, nanorods, deoxyribonucleic acid oligomers, nanoplatelets or a protein nucleic acid oligomer.

17. The method of claim 13, wherein the substituent is a DNA oligomer, a RNA oligomer, a fullerene, a substituted fullerene, a nanocrystal, a substituted nanocrystal, a nanorod, a substituted nanorod, a nanoplatelet, or a substituted nanoplatelet.

18. The method of claim 1, wherein the first medium enhances stability of the flavin moieties on the (n,m)-SWNTs comprising the (8,6)-SWNT, (7,7)-SWNT, or a combination thereof.

19. The method of claim 1, wherein the first medium comprises an aprotic polar solvent, a polar protic solvent, a non-polar solvent, or a combination thereof, and
the second medium, immiscible with the first medium, comprises an aprotic polar solvent, a polar protic solvent, a non-polar solvent, or a combination thereof.

20. The method of claim 1, wherein the first medium comprises water, propylene carbonate, ethylene carbonate, ethylene glycol, diglyme, triglyme, tetraglyme, butyrolactone, acetonitrile, benzonitrile, nitromethane, nitrobenzene, sulfolane, dimethylformamide, N-methylpyrrolidone, methanol, ethanol, propanol, isopropanol, butanol, tetrahydrofuran, benzene, toluene, ortho-xylene, meta-xylene, para-xylene, chlorobenzene, carbon tetrachloride, pentane, hexane, heptane, octane, dodecane, diethyl ether, methyl t-butyl ether, methylene chloride, chloroform, ethylene dichloride, trichloroethane, trichloroethylene, acetone, methyl ethyl ketone, methyl iso-butyl ketone, methyl iso-amyl ketone, cyclohexanone, methyl acetate, ethyl acetate, iso-propyl acetate, propyl acetate, butyl acetate, amyl acetate, 2-butoxyethanol acetate, or a combination thereof, and
the second medium comprises water, propylene carbonate, ethylene carbonate, ethylene glycol, diglyme, triglyme, tetraglyme, butyrolactone, acetonitrile, benzonitrile, nitromethane, nitrobenzene, sulfolane, dimethylformamide, N-methylpyrrolidone, methanol, ethanol, propanol, isopropanol, butanol, tetrahydrofuran, benzene, toluene, ortho-xylene, meta-xylene, para-xylene, chlorobenzene, carbon tetrachloride, pentane, hexane, heptane, octane, dodecane, diethyl ether, methyl t-butyl ether, methylene chloride, chloroform, ethylene dichloride, trichloroethane, trichloroethylene, acetone, methyl ethyl ketone, methyl iso-butyl ketone, methyl iso-amyl ketone, cyclohexanone, methyl acetate, ethyl acetate, iso-propyl acetate, propyl acetate, butyl acetate, amyl acetate, 2-butoxyethanol acetate, or a combination thereof.

21. The method of claim 1, wherein the first medium comprises a polar solvent, and the second medium comprises cyclohexanone, ethyl acetate, or a combination thereof.

22. The method of claim 1, wherein dispersing comprises sonicating the composition.

23. The method of claim 22, wherein dispersing further comprises subjecting the composition to a shear force, extensional force, compressive force, ultrasonic energy, electromagnetic energy, thermal energy, or a combination thereof.

24. A method for removing a surface defect in a nanocomposite, the method comprising:
disposing a nanocomposite in a first medium, the nanocomposite comprising:
an (n,m)-single wall carbon nanotube ((n,m)-SWNT); and
a plurality of flavin moieties disposed on the (n,m)-SWNT, a portion of the plurality of flavin moieties being arranged in a helix on the (n,m)-SWNT;
contacting the nanocomposite with a second medium; and
annealing the plurality of flavin moieties disposed on the (n,m)-SWNT to remove the surface defect from the nanocomposite to form an annealed nanocomposite.

25. The method of claim 24, wherein the surface defect comprises a discontinuity in the helix.

26. The method of claim 25, wherein annealing comprises:
removing the discontinuity; and
increasing a continuous length of the helix in the annealed nanocomposite.

27. The method of claim 26, wherein the continuous length of the helix is from 200 nm to 700 nm, based on a longitudinal distance along the (n,m)-SWNT.

28. The method of claim 24, wherein annealing comprises lowering a melting temperature of the plurality of flavin moieties disposed on the (n,m)-SWNT to a reduced melting temperature.

29. The method of claim 28, wherein lowering the melting temperature to the reduced melting temperature is accomplished by the second medium.

30. The method of claim 29, wherein annealing further comprises heating the nanocomposite to a temperature effective to mobilize the flavin moieties disposed on the (n,m)-SWNT, the temperature being based on the reduced melting temperature.

31. The method of claim 30, wherein the reduced melting temperature is from 30° C. to 100° C.

32. The method of claim 24, further comprising collecting the annealed nanocomposite.

33. The method of claim 24, wherein the (n,m)-SWNT comprises an (8,6)-SWNT, (7,7)-SWNT, or a combination thereof.

34. The method of claim 33, wherein the (n,m)-SWNT is the (8,6)-SWNT which comprises a first enantiomer of the (8,6)-SWNT in an amount greater than a second enantiomer of the (8,6)-SWNT.

35. The method of claim 34, wherein the first enantiomer is M-(8,6)-SWNT.

36. The method of claim 24, wherein the helix comprises a first handedness which is present in an amount greater than a second handedness.

37. The method of claim 36, wherein the first handedness of the helix is a plus (P)-handedness.

38. The method of claim 24, wherein the helix comprises a handedness which is different than the handedness of the (n,m)-SWNT.

39. The method of claim 38, wherein the annealed nanocomposite comprises a P-handed helix disposed on an M-(8,6)-SWNT, an M-handed helix disposed on a P-(8,6)-SWNT, or a combination thereof.

40. The method of claim 24, wherein the plurality of flavin moieties comprises flavin mononucleotide, flavin adenine dinucleotide, FC12 (10-dodecyl-7,8-dimethyl-10H-benzo[g]pteridine-2,4-dione), riboflavin, or a combination thereof.

41. The method of claim 24, wherein the first medium comprises an aprotic polar solvent, a polar protic solvent, a non-polar solvent, or a combination thereof, and
the second medium, which is immiscible with the first medium, comprises an aprotic polar solvent, a polar protic solvent, a non-polar solvent, or a combination thereof.

42. The method of claim 41, wherein the first medium comprises water, propylene carbonate, ethylene carbonate, ethylene glycol, diglyme, triglyme, tetraglyme, butyrolactone, acetonitrile, benzonitrile, nitromethane, nitrobenzene, sulfolane, dimethylformamide, N-methylpyrrolidone, methanol, ethanol, propanol, isopropanol, butanol, tetrahydrofuran, or a combination thereof, and
the second medium, which is immiscible with the first medium, comprises benzene, toluene, ortho-xylene, meta-xylene, para-xylene, chlorobenzene, carbon tetrachloride, pentane, hexane, heptane, octane, dodecane, diethyl ether, methyl t-butyl ether, methylene chloride, chloroform, ethylene dichloride, trichloroethane, trichloroethylene, acetone, methyl ethyl ketone, methyl iso-butyl ketone, methyl iso-amyl ketone, cyclohexanone, methyl acetate, ethyl acetate, iso-propyl acetate, propyl acetate, butyl acetate, amyl acetate, 2-butoxyethanol acetate, or a combination thereof.

43. The method of claim 41, wherein the first medium comprises a polar solvent, and the second medium comprises cyclohexanone, ethyl acetate, or a combination thereof.

44. The method of claim 24, wherein the helix of the annealed nanocomposite has a thermal stability greater than that of the nanocomposite before annealing.

45. The method of claim 24 wherein the annealed nanocomposite suppresses formation of bundles of the annealed nanocomposite with (n,m)-SWNTs, nanocomposites, or a combination thereof.

46. The method of claim 24, wherein the helix of the annealed nanocomposite has a repeat pattern of 2.5 nm as determined by X-ray diffraction.

47. The method of claim 24, wherein the helix is arranged in an 8/1 configuration such that 8 flavin moieties in the helix wrap around the (n,m)-SWNT per turn of the helix.

48. The method of claim 24, wherein the annealed nanocomposite is a superhelix.

49. A method for producing a superhelix nanocomposite, the method comprising:
forming a nanocomposite comprising:
an (n,m)-single wall carbon nanotube ((n,m)-SWNT); and
a helix comprising flavin moieties wrapped around the (n,m)-SWNT; and
coiling the nanocomposite to form the superhelix nanocomposite which comprises a writhe.

50. The method of claim 49, further comprising combining a plurality of superhelix nanocomposites to form a braided nanocomposite.

51. The method of claim 50, wherein the plurality of superhelix nanocomposites form the braided nanocomposite in response to a concentration of the superhelix nanocomposites being greater than a critical concentration for forming the braided nanocomposite.

52. The method of claim 50, further comprising controlling a distance between adjacent (n,m)-SWNTs of the plurality of superhelix nanocomposites in the braided nanocomposite.

53. The method of claim 52, wherein the distance between adjacent (n,m)-SWNTs of the plurality of superhelix nanocomposites in the braided nanocomposite is from 0.2 nm to 2 nm.

54. The method of claim 50, wherein an average diameter of the braided nanocomposite is from 2 nm to 6 nm.

55. The method of claim 50, wherein the number of superhelix nanocomposites in the braided nanocomposite comprises from 2 to 4 superhelix nanocomposites.

56. The method of claim 50, wherein the (n,m)-SWNTs of the plurality of superhelix nanocomposites in the braided nanocomposite comprises an (n,m)-met-SWNT and (n,m)-sem-SWNT.

57. The method of claim 56, wherein the (n,m)-met-SWNT is a (7,7)-SWNT, and the (n,m)-sem-SWNT is an (8,6)-SWNT.

58. The method of claim 57, wherein the (8,6)-SWNT comprises a first enantiomer in an amount greater than a second enantiomer.

59. The method of claim 58, wherein the first enantiomer is M-(8,6)-SWNT.

60. The method of claim 50, wherein the helix of the nanocomposite comprises a handedness which is different than a handedness of the (n,m)-SWNT.

61. The method of claim 60, wherein the helix of the nanocomposite comprises a P-handed helix disposed on an M-(8,6)-SWNT, an M-handed helix disposed on a P-(8,6)-SWNT, or a combination thereof.

62. The method of claim 50, wherein the helix of the nanocomposite comprises a groove between adjacent turns of the helix.

63. The method of claim 62, wherein the helix of the nanocomposite has a repeat pattern of 2.5 nm as determined by X-ray diffraction.

64. The method of claim 62, wherein, in each of the nanocomposites, the helix is arranged in an 8/1 configuration such that 8 flavin moieties in the helix wrap around the (n,m)-SWNT per turn of the helix.

65. The method of claim 62, wherein adjacent superhelix nanocomposites in the braided nanocomposite have interdigitated helices.

66. The method of claim 50, wherein the number of superhelix nanocomposites in the braided nanocomposite is self-limited.

67. The method of claim 50, wherein combining the plurality of superhelix nanocomposites to form the braided nanocomposite is reversible.

68. The method of claim 67, wherein the plurality of superhelix nanocomposites reversibly dissociate in response to a change in a condition comprising superhelix nanocomposite concentration, temperature, pH, displacement of the flavin moiety from the helix in the nanocomposite, or a combination thereof.

69. The method of claim 50, wherein the braided nanocomposite has a writhe periodicity from 10 nm to 520 nm.

70. The method of claim 69, wherein the braided nanocomposite comprises two superhelix nanocomposites, and the braided nanocomposite has a writhe periodicity from 10 to 230 nm.

71. The method of claim 69, wherein the braided nanocomposite comprises three superhelix nanocomposites, and the braided nanocomposite has a writhe periodicity from 10 to 100 nm.

72. The method of claim 50, wherein the (n,m)-SWNTs of the braided nanocomposite comprise an (n,m)-sem-SWNT and (n,m)-met-SWNT, and the braided nanocomposite has a Fano effect.

73. The method of claim 72, wherein photoluminescent emission of the (n,m)-sem-SWNT is quenched by the (n,m)-met-SWNT.

74. The method of claim 73, wherein the photoluminescent emission of the (n,m)-sem-SWNT is recovered from being quenched in response to increasing a distance between the (n,m)-sem-SWNT and (n,m)-met-SWNT.

75. The method of claim 74, wherein increasing a distance between the (n,m)-sem-SWNT and (n,m)-met-SWNT comprises a change in a condition comprising superhelix nanocomposite concentration, temperature, pH, displacement of the flavin moiety from the helix in the nanocomposite, or a combination thereof.

76. The method of claim 49, wherein the flavin moieties comprise flavin mononucleotide, flavin adenine dinucleotide, FC12 (10-dodecyl-7,8-dimethyl-10H-benzo[g]pteridine-2,4-dione), riboflavin, or a combination thereof.

77. A method for inducing photoluminescent emission in a superhelix nanocomposite, the method comprising:
irradiating a medium comprising a plurality of superhelix nanocomposites with primary radiation comprising an excitation wavelength; and
collecting photoluminescent emission from the superhelix nanocomposite,
wherein the superhelix nanocomposite comprises:
an (n,m)-single wall carbon nanotube ((n,m)-SWNT);
a helix comprising a plurality of flavin moieties wrapped around the (n,m)-SWNT; and
a writhe formed in response to coiling of the (n,m)-SWNT.

78. The method of claim 77, further comprising irradiating the medium with secondary radiation comprising the excitation wavelength and a quenching wavelength,
wherein the plurality of superhelix nanocomposites comprises:
a first superhelix nanocomposite in which the (n,m)-SWNT is an (n,m)-sem-SWNT; and
a second superhelix nanocomposite in which the (n,m)-SWNT is an (n,m)-met-SWNT; or
a combination thereof.

79. The method of claim 78, further comprising reversibly forming a braided nanocomposite in response to a concentration of the superhelix nanocomposites being greater than a critical concentration for forming the braided nanocomposite, the braided nanocomposite comprising two or more superhelix nanocomposites reversibly arranged in a braided helical configuration.

80. The method of claim 79, wherein the excitation wavelength excites an excitation channel in the first superhelix nanocomposite, and the quenching wavelength excites a quenching channel in the second superhelix nanocomposite.

81. The method of claim 80, wherein the photoluminescent emission is emitted by the first superhelix nanocomposite in response to irradiating the medium with the primary radiation.

82. The method of claim 81, wherein the photoluminescent emission is emitted by the first superhelix nanocomposite in response to irradiating the medium with the secondary radiation for the first superhelix nanocomposite which is not in the braided nanocomposite.

83. The method of claim 82, wherein the photoluminescent emission is emitted by the first superhelix nanocomposite in the braided nanocomposite in response to irradiating the medium with the secondary radiation, wherein the second superhelix nanocomposite is not in the braided nano composite.

84. The method of claim 83, wherein the photoluminescent emission is quenched before being emitted by the first superhelix nanocomposite in the braided nanocomposite in response to irradiating the medium with the secondary radiation, wherein the second superhelix nanocomposite is in the braided nanocomposite.

85. The method of claim 84, wherein the photoluminescent emission is recovered from being quenched in response to increasing a distance between the first superhelix nanocomposite and the second superhelix nanocomposite in the braided nanocomposite.

86. The method of claim 85, wherein increasing the distance between the first superhelix nanocomposite and the second superhelix nanocomposite in the braided nanocomposite comprises a change in a condition comprising superhelix nanocomposite concentration, temperature, pH, displacement of the flavin moieties from the helix in the nanocomposite, dissociation of the helix from the superhelix nanocomposite, or a combination thereof.

87. The method of claim 84, further comprising determining an amount of the first superhelix nanocomposite in the braided nanocomposite.

88. The method of claim 87, wherein the first superhelix nanocomposite and the second superhelix nanocomposite are internal calibration standards.

89. The method of claim 84, further comprising sensing an antigen by:
disposing the antigen in the medium prior to disposing the superhelix nanocomposite in the medium;
disposing the first superhelix nanocomposite of the braided nanocomposite in the medium, such that a concentration of the superhelix nanocomposite is below the critical concentration for forming the braided nanocomposite, wherein the first superhelix nanocomposite further comprises:
a first antibody disposed at a primary terminus of the first superhelix nanocomposite; and
a flexible member interposed between the first antibody and the primary terminus of the first superhelix nanocomposite;
binding the first antibody to the antigen;
disposing the second superhelix nanocomposite of the braided nanocomposite in the medium, such that the concentration of the superhelix nanocomposite is below the critical concentration for forming the braided nanocomposite, wherein the second superhelix nanocomposite further comprises:
a second antibody disposed at a primary terminus of the second superhelix nanocomposite; and
a flexible member interposed between the second antibody and the primary terminus of the second superhelix nanocomposite; and
binding the second antibody to the antigen.

90. The method of claim 89, wherein binding the first antibody and the second antibody to the antigen increases the concentration of the superhelix nanocomposite proximate to the antigen to be greater than the critical concentration for forming the braided nanocomposite such that the first superhelix nanocomposite and the second superhelix nanocomposite form the braided nanocomposite, the braided nanocomposite being bound to the antigen via the first antibody and the second antibody.

91. The method of claim 90, wherein the photoluminescent emission is collected from the medium to sense the antigen.

92. The method of claim 91, wherein an intensity of emission of the antigen is less than:
an intensity of the photoluminescent emission from irradiating the medium with the primary radiation,
an amount of photoluminescent emission lost due to quenching of the photoluminescent emission from the first superhelix nanocomposite by the second superhelix nanocomposite in the braided nanocomposite from irradiating the medium with the secondary radiation, or
a combination thereof.

93. The method of claim 90, wherein the first superhelix nanocomposite further comprises a first DNA sticky end disposed at a terminus opposing the primary terminus of the first superhelix nanocomposite, and the second superhelix nanocomposite further comprises a second DNA sticky end disposed at a terminus opposing the primary terminus of the second superhelix nanocomposite.

94. The method of claim 93, further comprising amplifying the sensing of the antigen by:
disposing a third superhelix nanocomposite in the medium, the third superhelix nanocomposite comprising:
a first DNA sticky end disposed at a primary terminus of the third superhelix nanocomposite; and
a third DNA sticky end disposed at a terminus opposing the primary terminus of the third superhelix nanocomposite; and
disposing a fourth superhelix nanocomposite in the medium, the fourth superhelix nanocomposite comprising:
a second DNA sticky end disposed at a primary terminus of the fourth superhelix nanocomposite; and
a fourth DNA sticky end disposed at a terminus opposing the primary terminus of the fourth superhelix nanocomposite,
wherein the third DNA sticky end comprises a DNA sequence which is complementary to that of the first DNA sticky end, the fourth DNA sticky end comprises a DNA sequence which is complementary to that of the second DNA sticky end, the (n,m)-SWNT of the third superhelix nanocomposite is an (n,m)-sem-SWNT, and the (n,m)-SWNT of the fourth superhelix nanocomposite is an (n,m)-met-SWNT.

95. The method of claim 94, wherein the third superhelix nanocomposite emits the photoluminescent emission in response to irradiation with the primary radiation, the fourth superhelix nanocomposite quenches the photoluminescent emission from the third superhelix nanocomposite in response to irradiation of the medium with the secondary radiation when the third and fourth superhelix nanocomposites are adjacently disposed in a braided helical configuration.

96. The method of claim 95, further comprising:
attaching the third superhelix nanocomposite to the antigen by binding the third DNA sticky end of the third superhelix nanocomposite to the first DNA sticky end of the first superhelix nanocomposite having a first antibody bound to the antigen; and
attaching the fourth superhelix nanocomposite to the antigen by binding the fourth DNA sticky end of the fourth superhelix nanocomposite to the second DNA sticky end of the second superhelix nanocomposite having a second antibody bound to the antigen; and
extending the braided nanocomposite comprising the first and second superhelix nanocomposites and bound to the antigen by forming a braided helical configuration between the third and fourth superhelix nanocomposites upon attaching the third and fourth superhelix nanocomposites to the antigen.

97. The method of claim 96, wherein extending the braided nanocomposite bound to the antigen by attaching the third and fourth superhelix nanocomposites to the antigen increases the intensity of the photoluminescent emission in response to irradiating the medium with the primary radiation and increases the amount of quenching of the photoluminescent emission in response to irradiating the medium with the secondary radiation to amplify the sensing of the antigen.

98. The method of claim 78, wherein the excitation wavelength is from 300 nm to 400 nm, 650 nm to 750 nm, or a combination thereof.

99. The method of claim 98, wherein the quenching wavelength is from 480 nm to 520 nm.

100. The method of claim 98, wherein the photoluminescent emission is from 1150 nm to 1250 nm.

101. The method of claim 78, wherein the (n,m)-sem-SWNT is an (8,6)-SWNT, and the (n,m)-met-SWNT is a (7,7)-SWNT.

102. The method of claim 77, wherein the plurality of flavin moieties comprises flavin mononucleotide, flavin adenine dinucleotide, FC12 (10-dodecyl-7,8-dimethyl-10H-benzo[g]pteridine-2,4-dione), riboflavin, or a combination thereof.

103. A braided nanocomposite comprising:
a plurality of superhelix nanocomposites reversibly combined in a braided helical configuration, each of the superhelix nanocomposites comprising:
an (n,m)-single wall carbon nanotube ((n,m)-SWNT);
a plurality of flavin moieties disposed in a helix which is self-assembled around the (n,m)-SWNT; and
a writhe formed by coiling of the (n,m)-SWNT,
wherein the plurality of superhelix nanocomposites reversibly combines to form the braided nanocomposite in response to a concentration of the superhelix nanocomposites being greater than a critical concentration for forming the braided nanocomposite;
the (n,m)-SWNT comprises an (n,m)-sem-SWNT, (n,m)-met-SWNT, or a combination thereof; and
the helix has a continuous length from 200 nm to 700 nm, based on a longitudinal distance along the (n,m)-SWNT.

104. The braided nanocomposite of claim 103, wherein the flavin moieties comprise flavin mononucleotide, flavin adenine dinucleotide, FC12 (10-dodecyl-7,8-dimethyl-10H-benzo[g]pteridine-2,4-dione), riboflavin, or a combination thereof.

105. The braided nanocomposite of claim 104, wherein the flavin moieties are substituted with a substituent comprising a complex chiral center; the complex chiral center being a R- or L-ribityl, R- or L-ribityl phosphate, R- and L-ribityl diphosphatic adenine; R- or L-arabityl, R- or L-arabityl phosphate, R- and L-arabityl diphosphatic adenine; R- or L-xylityl, R- or L-xylityl phosphate, R- and L-xylityl diphosphatic adenine; R- or L-xylityl, R- or L-xylityl phosphate, R- and L-xylityl diphosphatic adenine; R- or L-lyxytyl, R- or L-lyxytyl phosphate, or R- and L-lyxytyl diphosphatic adenine.

106. The braided nanocomposite of claim 103, wherein the (n,m)-sem-SWNT is an (8,6)-SWNT, and the (n,m)-met-SWNT is an (7,7)-SWNT.

107. The braided nanocomposite of claim 106, wherein the (8,6)-SWNT comprises a first enantiomer present in an amount greater than a second enantiomer of the (8,6)-SWNT.

108. The braided nanocomposite of claim 107, wherein the first enantiomer is an M-(8,6)-SWNT.

109. The braided nanocomposite of claim 103, wherein the helix comprises a first handedness which is present in an amount greater than a second handedness.

110. The braided nanocomposite of claim 109, wherein the first handedness of the helix is a plus (P)-handedness.

111. The braided nanocomposite of claim 103, wherein the helix comprises a handedness which is different than a handedness of the (n,m)-SWNT.

112. The braided nanocomposite of claim 111, wherein the helix is a P-handed helix disposed on an M-(8,6)-SWNT, an M-handed helix disposed on a P-(8,6)-SWNT, or a combination thereof.

113. The braided nanocomposite of claim 103, wherein the helix disposed on the (n,m)-SWNT has a repeat pattern of 2.5 nm as determined by X-ray diffraction.

114. The braided nanocomposite of claim 103, wherein the helix disposed on the (n,m)-SWNT is arranged in an 8/1 configuration such that 8 flavin moieties in the helix wrap around the (n,m)-SWNT per turn of the helix.

115. The braided nanocomposite of claim 103, wherein a distance between adjacent (n,m)-SWNTs of the plurality of superhelix nanocomposites in the braided nanocomposite is from 0.2 nm to 2 nm.

116. The braided nanocomposite of claim 103, wherein an average diameter of the braided nanocomposite is from 2 nm to 6 nm.

117. The braided nanocomposite of claim 103, wherein the number of superhelix nanocomposites in the braided nanocomposite comprises from 2 to 4 superhelix nanocomposites.

118. The braided nanocomposite of claim 103, wherein the helix comprises a groove between adjacent turns of the helix.

119. The braided nanocomposite of claim 118, wherein adjacent superhelix nanocomposites in the braided nanocomposite are arranged in the braided helical configuration such that the helices of adjacent superhelix nanocomposites are interdigitated.

120. The braided nanocomposite of claim 103, wherein the plurality of superhelix nanocomposites reversibly combine in response to a change in a condition comprising superhelix nanocomposite concentration, temperature, pH, displacement of flavin moieties from the helix in the superhelix nanocomposite, or a combination thereof.

121. The braided nanocomposite of claim 103, wherein the braided nanocomposite has a writhe periodicity from 10 nm to 520 nm.

122. The braided nanocomposite of claim 121, wherein the braided nanocomposite comprises two superhelix nanocomposites, and the braided nanocomposite has a writhe periodicity from 10 to 230 nm.

123. The braided nanocomposite of claim 121, wherein the braided nanocomposite comprises three superhelix nanocomposites, and the braided nanocomposite has a writhe periodicity from 10 to 100 nm.

124. The braided nanocomposite of claim 103, wherein the plurality of superhelix nanocomposites comprises:
a first superhelix nanocomposite in which the (n,m)-SWNT is an (n,m)-sem-SWNT; and
a second superhelix nanocomposite in which the (n,m)-SWNT is an (n,m)-met-SWNT, and
the braided nanocomposite has a Fano effect such that an excitation wavelength excites an excitation channel in the (n,m)-sem-SWNT of the first superhelix nanocomposite, and a quenching wavelength excites a quenching channel in the (n,m)-met-SWNT of the second superhelix nanocomposite.

125. The method of claim 124, wherein photoluminescent emission of the (n,m)-sem-SWNT is quenched by the (n,m)-met-SWNT.

126. The method of claim 125, wherein the photoluminescent emission of the (n,m)-sem-SWNT is recovered from being quenched in response to increasing a distance between the first superhelix nanocomposite and the second superhelix nanocomposite in the braided nanocomposite.

127. A nanosensor system comprising:
a power unit to generate power;
a sensor configured to generate an electrical signal in response to sensing an event and electrically connected to the power unit;
a signal converter to receive and convert the electrical signal into an electrical pulse and to output the electrical pulse, the signal converter being electrically connected to the power unit and sensor; and
an optical modulator comprising:
a light source to output a quenching wavelength which is modulated between an on-state and an off-state at a frequency of the electrical pulse from the signal converter, the light source being electrically connected to the power unit and signal converter;
an optical cavity comprising:
a cavity to contain a composition comprising the braided nanocomposite of claim 103; and
a plurality of walls disposed about the cavity to transmit radiation.

128. The nanosensor system of claim 127, wherein the power unit comprises a photovoltaic device, battery, motor, or a combination thereof.

129. The nanosensor system of claim 128, wherein the power unit is the photovoltaic device which generates power in response to receiving an excitation wavelength from an external light source.

130. The nanosensor system of claim 129, wherein the electrical signal generated by the sensor is an analog signal which is proportional to an amplitude of the event.

131. The nanosensor system of claim 130 wherein the event comprises temperature, pH, displacement, pressure, position, actuation, flow, concentration, or a combination thereof.

132. The nanosensor system of claim 130, wherein the signal convertor converts the analog signal, and the electrical pulse is a digital pulse.

133. The nanosensor system of claim 132, wherein the light source is a laser, light emitting diode, flash lamp, or a combination thereof.

134. The braided nanocomposite of claim 133, wherein the plurality of superhelix nanocomposites in the braided nanocomposite comprises:
a first superhelix nanocomposite in which the (n,m)-SWNT is an (n,m)-sem-SWNT; and
a second superhelix nanocomposite in which the (n,m)-SWNT is an (n,m)-met-SWNT, and
the braided nanocomposite has a Fano effect such that the excitation wavelength excites an excitation channel in the (n,m)-sem-SWNT of the first superhelix nanocomposite, and the quenching wavelength excites a quenching channel in the (n,m)-met-SWNT of the second superhelix nanocomposite.

135. The braided nanocomposite of claim 134, wherein the optical cavity is configured to transmit a modulated photoluminescent emission comprising:
photoluminescent emission which is emitted by the (n,m)-met-SWNT in response to irradiation by the excitation wavelength, and which is modulated in response to irradiation by the quenching wavelength such that the photoluminescent emission is emitted when the quenching wavelength has the off-state and is quenched when the quenching wavelength has the on-state.

136. The braided nanocomposite of claim 135, wherein a time of occurrence of the event which is sensed by the sensor is encoded in the modulated photoluminescent emission and corresponds to the photoluminescent emission being quenched.

137. The braided nanocomposite of claim 135, wherein the excitation wavelength is a continuous wave.

138. The braided nanocomposite of claim 137, wherein excitation wavelength is from 300 nm to 400 nm, 650 nm to 750 nm, or a combination thereof.

139. The method of claim 138, wherein the quenching wavelength is from 480 nm to 520 nm.

140. The method of claim 139, wherein the photoluminescent emission is from 1150 nm to 1250 nm.

141. The method of claim 135, wherein photoluminescent emission of the (n,m)-sem-SWNT is recovered from being quenched in response to increasing a distance between the first superhelix nanocomposite and the second superhelix nanocomposite in the braided nanocomposite.

142. The nanosensor system of claim 135, wherein the composition disposed in the optical cavity further comprises a medium which is optically transparent to the excitation wavelength and photoluminescent wavelength.

143. A nanotransistor comprising:
a source electrode;
a drain electrode opposingly disposed to the source electrode; and
a gate electrode disposed proximate to the source electrode and drain electrode, the gate electrode comprising the braided nanocomposite of claim 103.

144. The nanotransistor of claim 143, wherein the plurality of superhelix nanocomposites comprises:
a first superhelix nanocomposite in which the (n,m)-SWNT is an (n,m)-sem-SWNT; and
a second superhelix nanocomposite in which the (n,m)-SWNT is an (n,m)-met-SWNT, and
the plurality of superhelix nanocomposites is arranged such that the first superhelix nanocomposite and second superhelix nanocomposite are spaced apart by a separation such that the braided helical configuration is absent in the braided nanocomposite.

145. The nanotransistor of claim 144, wherein the first superhelix nanocomposite directly contacts the source electrode and drain electrode to interconnect the source electrode and drain electrode; and the second superhelix nanocomposite is detached from the source electrode, gate electrode, or a combination thereof.

146. The nanotransistor of claim 145, wherein the separation is removed in response to a change in a condition such that the first superhelix nanocomposite and second superhelix nanocomposite reversibly combine to form the braided helical configuration.

147. The nanotransistor of claim 146, wherein the condition comprises temperature, pH, application of a voltage, application of current, irradiation with electromagnetic radiation, or a combination thereof.

148. The nanotransistor of claim 146, wherein the separation comprises a removable partition, and the condition comprises removal of the removable partition.

149. The nanotransistor of claim 147, wherein the nanotransistor is configured to operate in the presence of a liquid disposed on the source electrode, gate electrode, drain electrode, or a combination thereof.

150. A nanoactuator comprising:
a medium; and
the braided nanocomposite of claim 103 disposed in the medium,
wherein the nanoactuator is configured to be actuated between a non-actuated state and an actuated state in response to a change in a condition,
in the non-actuated state the plurality of superhelix nanocomposites are spaced apart by a separation such that the braided helical configuration is absent in the braided nanocomposite; and
in the actuated state the separation is removed in response to the change in condition such that the plurality of superhelix nanocomposites reversibly combines to form the braided helical configuration.

151. The nanotransistor of claim 150, wherein the condition comprises temperature, pH, voltage, electrical current, a chemical stimulus, mechanical force, irradiation with electromagnetic radiation, or a combination thereof.

152. A structural nanoprobe comprising:
a medium; and
the braided nanocomposite of claim 103 disposed in the medium,
wherein the plurality of superhelix nanocomposites in the braided nanocomposite comprises:
a first superhelix nanocomposite in which the (n,m)-SWNT is an (n,m)-sem-SWNT; and
a second superhelix nanocomposite in which the (n,m)-SWNT is an (n,m)-met-SWNT, and
the braided nanocomposite has a Fano effect such that:
the (n,m)-sem-SWNT emits photoluminescent emission in response to irradiation with primary radiation comprising an excitation wavelength,
the photoluminescent emission from the (n,m)-sem-SWNT is quenched by the (n,m)-met-SWNT in response to irradiation with secondary radiation comprising the excitation wavelength and a quenching wavelength when the first and second superhelix nanocomposites have the braided helical configuration, and
the photoluminescent emission from the (n,m)-sem-SWNT is emitted in response to irradiation with the secondary radiation when the first and second superhelix nanocomposites are spaced apart by a separation such that the braided helical configuration is absent in the braided nanocomposite.

153. The structural nanoprobe of claim 152, wherein the first and second superhelix nanocomposites are spaced apart by a separation in response to the medium being subjected to mechanical fatigue, failure, stress, slip, cracking, expansion, or a combination thereof.
